(19) United States
(12) Patent Application Publication
(10) Pub. No.: US 2026/0251983 A1
(43) Pub. Date: Aug. 27, 2026

(54) SYSTEMS AND METHODS FOR MULTI-TASK BASELINE MODELS IN SEMICONDUCTOR METROLOGY AND INSPECTION APPLICATIONS

(71) Applicant: Gauss Labs Inc., Palo Alto, CA (US)

(72) Inventors: Yonghyun Kim, Seongnam-si (KR); Jihyung Ko, Pyeongtaek-si (KR); Il Koo Kim, Seongnam-si (KR); Inae Kim, Seoul (KR)

(21) Appl. No.: 19/534,561

(22) Filed: Feb. 9, 2026

Related U.S. Application Data
(60) Provisional application No. 63/761,462, filed on Feb. 21, 2025.
(60) Provisional application No. 63/867,547, filed on Aug. 20, 2025.

(51) Int. Cl. G03F 7/00; G06N 3/0455; G06N 3/088

(52) U.S. Cl. CPC G03F 7/706841; G03F 7/70655; G03F 7/706837; G06N 3/0455; G06N 3/088

(57) ABSTRACT

Described are systems and methods for unsupervised detection and segmentation of unknown objects in semiconductor metrology and inspection applications. Methods can include receiving a first dataset comprising one or more unknown objects and a second dataset comprising a set of reference objects, generating a set of input embeddings of the one or more unknown objects by applying an encoder to the first dataset, generating a set of correlated embeddings by applying a convolutional neural network (CNN) to the set of input embeddings and reference embeddings, generating a set of reference-attentioned embeddings of the one or more unknown objects, and training a machine learning (ML) model using the output of the reference-attentioned model.

### CROSS-REFERENCE TO RELATED APPLICATIONS

This application claims the benefit of U.S. Provisional Application No. 63/867,547, filed Aug. 20, 2025, and U.S. Provisional Application No. 63/761,462, filed Feb. 21, 2025, each of which is incorporated by reference herein in its entirety.

### BACKGROUND

Metrology and Inspection (MI) plays an important role in semiconductor manufacturing. Recently, MI methods have faced significant technical challenges due to increasing noise and reduced quality (or clarity) in semiconductor images of objects patterned on wafers. For example, semiconductor chips can have node sizes measured in nanometers or less to increase density and miniaturization of features on a chip. While Convolutional Neural Networks (CNNs) have shown promising results, their adoption in MI remains practically limited due to the need for extensive labeled datasets and the absence of widely-used backbone networks optimized for semiconductor images.

Recognized herein is an unmet need for systems and methods that can at least use unlabeled datasets of marginal semiconductor images to train a machine learning model for use in MI and downstream applications.

### SUMMARY

To address common limitations in MI, herein is provided an unsupervised learning architecture suitable for MI tasks or “SiliconBASE.” The SiliconBASE architecture can enable robust feature extraction by utilizing unlabeled data, providing a backbone model adaptable to various downstream applications, including object detection and object segmentation. Furthermore, reference object detection (ROD) and reference object segmentation (ROS), described herein, can enable flexible object recognition without predefined categories, thereby significantly improving generalization ability of the architecture herein. Extensive studies, provided herein, demonstrate the unsupervised learning architecture of SiliconBASE can achieve superior performance compared to supervised models such as Mask-RCNN, even when trained on limited datasets, and additionally can surpass human annotation in technically challenging cases. This architecture can establish a scalable, high-performance baseline for MI applications in the semiconductor industry. The SiliconBASE architecture described herein is further applicable to larger datasets and additional downstream tasks, which may enhance the generalization and efficiency of the architecture in some cases.

In an aspect, disclosed herein is a method for unsupervised detection and segmentation of unknown objects, the method comprising: (a) receiving a first dataset comprising one or more unknown objects, wherein the set of reference objects comprises a set of reference embeddings associated with instances of a class of at least one unknown object or the reference objects; (b) generating a set of input embeddings of the one or more unknown objects by applying an encoder to the first dataset; (c) generating a second set of correlated embeddings of the one or more unknown objects by applying a Convolutional Neural Network (CNN) model to the set of input embeddings and the set of reference embeddings, wherein the set of correlated embeddings is used to generate at least a detection overlay of the one or more unknown objects; (d) generating a set of referenced-attentioned embeddings of the one or more unknown objects by applying a referenced-attentioned model to the set of input embeddings and the set of reference embeddings, wherein the set of referenced-attentioned embeddings is used to generate at least a segmentation overlay of the one or more unknown objects; and (e) training a Machine Learning (ML) model using at least one of the detection overlay or the segmentation overlay, wherein the trained ML model is used to predict at least one of a set of detection characteristics or a set of segmentation characteristics with a confidence score.

In some embodiments, the method further comprises predicting, by the trained ML model, at least one of (i) a set of detection characteristics of the one or more unknown objects, or (ii) a set of detection characteristics of other objects of the same class. In some embodiments, each set of detection characteristics comprises at least a location of the one or more unknown objects or locations of the other objects patterned on a wafer using a semiconductor process. In some embodiments, the method further comprises predicting, by the trained ML model, at least one of (i) a set of segmentation characteristics of the one or more unknown objects, or (ii) a set of segmentation characteristics of other objects of the same class. In some embodiments, each set of segmentation characteristics comprises at least metrology measurements of the one or more unknown objects or metrology measurements of the other objects, patterned on the wafer using a semiconductor process. In some embodiments, the first dataset comprises at least an image of the one or more unknown objects patterned on a wafer using a semiconductor process. In some embodiments, the first dataset comprises at least an image of the one or more unknown objects obtained using Scanning Electron Microscopy (SEM) or Transmission Electron Microscopy (TEM). In some embodiments, the second dataset comprises at least images of the set of reference objects patterned on a wafer using a semiconductor process. In some embodiments, the second dataset comprises at least images of the set of reference objects obtained using SEM or TEM. In some embodiments, the method further comprises generating the set of input embeddings by using a vision encoder to determine a dimension of the first dataset comprising a number of channels and a size. In some embodiments, the method further comprises generating the set of correlated embeddings by using a mask region-based CNN (mask-RCNN) model comprising a dynamic anchor model to determine a grid of base anchors of the first dataset or the set of reference objects. In some embodiments, the method further comprises generating the set of reference-attentioned embeddings by using a multi-head attention model to obtain a low-resolution reference-attentioned mask. In some embodiments, the method further comprises generating the instances of the class of the at least one unknown object by applying a set of operations to the first dataset, thereby obtaining the second dataset. In some embodiments, the method further comprises using an output of the trained ML model in Reference Object Detection (ROD) in a semiconductor process for determining a set of detection characteristics of the one or more unknown objects or a plurality of other objects patterned by a semiconductor process. In some embodiments, each set of detection characteristics comprises at least one of (i) a set of positioning measurement locations of the one or more unknown objects or the plurality of other objects, or (ii) an issue in a hierarchical structure comprising the one or more unknown objects or the plurality of other objects, patterned by the semiconductor process. In some embodiments, the method further comprises using an output of the trained ML model in Reference Object Segmentation (ROS) in a semiconductor process for determining a set of segmentation characteristics of the one or more unknown objects or a plurality of other objects patterned by a semiconductor process. In some embodiments, each set of segmentation characteristics comprises at least a metrology of the one or more unknown objects or the plurality of other objects, patterned by the semiconductor process. In some embodiments, the method further comprises using an output of the trained ML model in Metrology and Inspection (MI) in a semiconductor process for characterizing at least a metrology of the one or more unknown objects or a plurality of other objects, patterned by a semiconductor process. In some embodiments, the method further comprises removing artifacts from the first dataset or the second dataset prior to determining the set of correlated embeddings. In some embodiments, the detection overlay or the segmentation overlay is embedded with data associated with a class of the at least one unknown object, a confidence score of the class, a label of the at least one unknown object, a confidence score of the label, an identification of the at least one unknown object, or a confidence score of the identification. In some embodiments, the trained ML model is trained by using reference-based training on the first dataset or the second dataset. In some embodiments, the trained ML model is validated by determining (i) a difference between the detection overlay and a detection overlay determined by domain expertise, or (ii) a difference between the segmentation overlay and a segmentation overlay determined by domain expertise. In some embodiments, the method further comprises repeating the method until determining the detection overlay or the segmentation overlay for all known objects or substantially all unknown objects of the first dataset. In some embodiments, an accuracy of the trained ML model is determined using Average Precision (AP), average recall, or mean Intersection Over the Union (IOU). In some embodiments, the accuracy is at least 90%. In some embodiments, the method further comprises using an output of the trained ML model to determine or predict an anomaly in an unknown object patterned on a wafer using a semiconductor process. In some embodiments, the method further comprises using an output of the trained ML model to search for an unknown object patterned on a wafer using a semiconductor process.

In an another aspect, disclosed herein is a computer program product for unsupervised detection and segmentation of unknown objects, the computer program product comprising at least one non-transitory computer-readable medium having computer-readable program code portions embodied therein, the computer-readable program code portions comprising: an executable portion configured receive a first dataset comprising one or more unknown objects and a second dataset comprising a set of reference objects, wherein the set of reference objects comprises a set of reference embeddings associated with instances of a class of at least one unknown object or the reference objects; an executable portion configured to generate a set of input embeddings of the one or more unknown objects by applying an encoder to the first dataset; an executable portion configured to generate a set of correlated embeddings of the one or more unknown objects by applying a convolutional neural network (CNN) model to the set of input embeddings and the set of reference embeddings, wherein the set of correlated embeddings is used to generate at least a detection overlay of the one or more unknown objects; an executable portion configured to generate a set of referenced-attentioned embeddings of the one or more unknown objects by applying a referenced-attentioned model to the set of input embeddings and the set of reference embeddings, wherein the set of referenced-attentioned embeddings is used to generate at least a segmentation overlay of the one or more unknown objects; and an executable portion configured to train a machine learning (ML) model using at least one of the detection overlay or the segmentation overlay, wherein the trained ML model is used to predict at least one of a set of detection characteristics or a set of segmentation characteristics with a confidence score.

In another aspect, disclosed herein is a system comprising at least one processor and instructions executable by the at least one processor to cause the at least one processor to perform operations comprising: (a) receiving a first dataset comprising one or more unknown objects and a second dataset comprising a set of reference objects, wherein the set of reference objects comprises a set of reference embeddings associated with instances of a class of at least one unknown object or the reference objects; (b) generating a set of input embeddings of the one or more unknown objects by applying an encoder to the first dataset; (c) generating a set of correlated embeddings of the one or more unknown objects by applying a convolutional neural network (CNN) model to the set of input embeddings and the set of reference embeddings, wherein the set of correlated embeddings is used to generate at least a detection overlay of the one or more unknown objects; (d) generating a set of referenced-attentioned embeddings of the one or more unknown objects by applying a referenced-attentioned model to the set of input embeddings and the set of reference embeddings, wherein the set of referenced-attentioned embeddings is used to generate at least a segmentation overlay of the one or more unknown objects; and (e) training a machine learning (ML) model using at least one of the detection overlay or the segmentation overlay, wherein the trained ML model is used to predict at least one of a set of detection characteristics or a set of segmentation characteristics with a confidence score.

Additional aspects and advantages of the present disclosure will become readily apparent from the following detailed description, wherein only illustrative embodiments of the present disclosure are shown and described. As will be realized, the present disclosure is capable of other and different embodiments, and its several details are capable of modifications in various obvious respects, all without departing from the present disclosure. Accordingly, the drawings and description are to be regarded as illustrative in nature and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the present disclosure contained in the specification, the specification is intended to supersede and/or take precedence over any such contradictory material.

### BRIEF DESCRIPTION OF THE DRAWINGS

The novel features of the present disclosure are set forth with particularity in the appended claims. A better understanding of the features and advantages of the present disclosure will be obtained by reference to the following detailed description that sets forth illustrative embodiments, in which the principles of the present disclosure are utilized, and the accompanying drawings of which:

FIG. 1 depicts a non-limiting example of a system architecture diagram for performing methods for unsupervised detection and segmentation of unknown objects, in some embodiments.

FIG. 2 depicts a non-limiting example of generated images with object masks, in some embodiments. Each image contains objects, with the corresponding segmentation masks overlaid as semi-transparent regions.

FIG. 3 depicts a non-limiting example of using a training dataset to perform systems and methods herein, in some embodiments.

FIG. 4 depicts a non-limiting example of representative types of images generated to reflect variations in real-world conditions, in some embodiments.

FIG. 5 depicts a non-limiting example of detection and segmentation accuracy measured in terms of COCO Average Precision (AP) for different variation types (e.g., base, blurred, noise, offset, ratio, roughness, and shift), in some embodiments.

FIG. 6 depicts a non-limiting example of detection and segmentation results, in some embodiments.

FIG. 7 depicts a non-limiting example of a user workflow for a computer program product of systems and methods for semiconductor metrology and inspection applications.

FIG. 8 depicts a non-limiting example of hierarchical organization of a semantic object, in some embodiments.

FIGS. 9A-9C depict a non-limiting example of a component flow as shown and described, in some embodiments. FIG. 9A depicts a non-limiting example of a user-specified manipulatable object. FIG. 9B depicts a non-limiting example of a user selecting a target object from a dataset. FIG. 9C depicts a non-limiting example of a user adding an Image Source component to the selected object.

FIG. 10 depicts a non-limiting example of processing components as shown and described, in some embodiments.

FIG. 11 depicts a non-limiting example of a user adding a new metrology process, in some embodiments.

FIGS. 12A-12B depict a non-limiting example of the Canvas as shown and described, in some embodiments. FIG. 12A depicts a non-limiting example of a 2D Canvas. FIG. 12B depicts a non-limiting example of a 3D Canvas.

FIGS. 13A-13B depict non-limiting examples of a non-color overlay and a metric overlay, in some embodiments. FIG. 13A depicts a non-limiting example of a color overlay.

FIG. 13B depicts a non-limiting example of a metric overlay.

FIG. 14 depicts a non-limiting example of a multi-query graph, in some embodiments.

FIG. 15 depicts a non-limiting example of Chart Suggestions, in some embodiments.

FIG. 16 depicts a non-limiting example of the code editor window, in some embodiments.

FIG. 17 depicts a non-limiting example of the details window, in some embodiments.

FIG. 18 depicts a non-limiting example of a duplicated public Component Pack, in some embodiments.

FIG. 19 depicts a non-limiting example of available public Component Packs in the Public tab, in some embodiments.

FIG. 20 depicts a non-limiting example of a computing device configured to perform methods herein, in some embodiments.

FIG. 21 depicts a non-limiting example of a web/mobile application provision system configured to perform methods herein, in some embodiments.

FIG. 22 depicts a non-limiting example of a cloud-based web/mobile application provision system configured to perform methods herein, in some embodiments.

### DETAILED DESCRIPTION

While various embodiments of the present disclosure have been shown and described herein, such embodiments are provided by way of example only. Numerous variations, changes, or substitutions may occur without departing from the present disclosure. It should be understood that various alternatives to the embodiments of the present disclosure described herein may be employed.

### Overview

In semiconductor manufacturing, Metrology and Inspection (MI) processes can be important at many stages. As semiconductor structures (or objects) become smaller, distinguishing details in images, SEM images, has become increasingly technically challenging due to higher noise levels, reduced clarity, marginal resolution, and the like. For example, increasing noise can be caused by greater structural complexity and miniaturization of objects and features of objects patterned on wafers. As in general photography, capturing smaller and more intricate objects often results in more noise or blur thereby making objects and features of objects technically challenging to distinguish. Further, compared to the present disclosure, other approaches typically operate based on rule-based profiles, conceptually similar to defining a peak when the center pixel is greater than its neighbors. Under technically challenging conditions such as high noise, multiple false peaks may appear, thereby leading to incorrect measurements. In the case of blur, such peaks might not be detected at all.

Some approaches, such as threshold-based and linear-based methods described in Mochi, I., et al., “Open-source software for SEM metrology,” in Photomask Technology 2020, 11518, 58-67, SPIE (2020), which is incorporated by reference herein in its entirety, have been widely used in MI. While these methods may demonstrate marginal performance in some cases, they can struggle under challenging technical conditions, e.g., different semiconductor processes across different recipes and equipment. For example, setting up a metrology recipe can be technically complex, and even when overall measurement values are obtained, individual measurements can fail or yield low-precision results.

Recently, Convolutional Neural Networks (CNNs), such as those described in Saib, M., et al., “Advanced characterization of 2d materials using SEM image processing and machine learning,” in Metrology, Inspection, and Process Control XXXVIII, 12955, 216-230, SPIE (2024); Kim, M., et al., “Frequency-informed deep-learning denoising method supporting sub-nm metrology for high NA EUV lithography,” in DTCO and Computational Patterning II, 12495, 307-313, SPIE (2023); Kim, Y., et al., “Universal denoiser to improve metrology throughput,” in Metrology, Inspection, and Process Control XXXVIII, 12955, 782-793, SPIE (2024); and Okuda, T. et al., “High throughput CD-SEM metrology using image denoising based on deep learning,” in Metrology, Inspection, and Process Control XXXVIII, 12955, 481-488, SPIE (2024), each of which is incorporated by reference herein in its entirety, have shown promising results in MI applications. However, CNN-based approaches can usually require an unacceptable time, e.g., at least many weeks, to collect large training datasets, manually annotate images, and train models. This is at least one factor which can make it difficult to adopt CNN-based approaches in the semiconductor field. For example, adopting CNNs typically requires weeks of effort and a large number of annotations. Since these methods may be applied across a wide range of wafer inspection tasks, such time- and labor-intensive processes are inefficient and less productive. Moreover, due to the workforce structure in the semiconductor industry, where dedicated AI engineers or software developers are often limited, it is particularly technically challenging and impractical to implement such methods in MI. Therefore, recognize herein is the need for systems and methos that can streamline these processes while achieving better performance.

Despite their adoption for some use cases, use of CNNs in MI remains technically deficient due to at least generalizability for all or substantially all use cases. Examples of contributing technical factors can include lack of public datasets and the absence of backbone networks optimized for semiconductor images. Compared to other approaches, systems and methods herein can apply unsupervised learning to user-domain data thereby enabling the training and generation of high-performance models designed to the user's devices and environments in semiconductor manufacturing across all or substantially all use cases. Models herein (or SiliconBASE) can effectively process and analyze the wide variety of semiconductor images generated by different devices, instruments, and tools under different and innumerable conditions. For example, devices, instruments, and tools can refer to measurement equipment in different environments. Environments can abstractly represent the various conditions associated with them across different semiconductor manufacturers. In such cases, models are specifically trained to a user's specific image metrology context thereby making such models less generalizable. Practically, even within the same semiconductor manufacturer, or across different manufacturers, various SEM and TEM instruments produce images with distinct visual characteristics and artifacts. Therefore, recognized herein is a need for models capable of handling these unique technical challenges.

An example of this is the SiliconBASE architecture, described herein, which is designed for semiconductor applications. Systems and methods herein include additional application features, such as Reference Object Detection (ROD) and Reference Object Segmentation (ROS), described herein. ROD and ROS differ from general object detection and segmentation in several important technical ways. In contrast to other models, which may recognize only the domains seen during training, ROD and ROS can enable flexible object recognition at the inference stage by receiving and using embeddings of reference objects. This can allow the model to detect objects dynamically without being restricted to predefined categories seen during training. Further, systems and methods herein can provide a strong baseline for various downstream tasks in the semiconductor field. Instead of relying on human-annotated labels, systems and methods herein provide a dataset generation method for two key MI applications-object detection and segmentation-by leveraging large-scale unlabeled image datasets. For example, in general object recognition, it may not possible or practical to detect or recognize objects that were not included during training. Compared to other approaches, methods herein can detect target objects specified at inference time, even if they were not part of the training dataset. As a simple illustration, unlike methods herein, other approaches might be trained on domains such as dogs, cats, or humans but cannot detect an object in another domain, such as a water bottle, if it was not seen during training. In the context of MI, domains can be closely related to devices and environments. For example, TEM and SEM represent different domains. Even within TEM, variations in imaging equipment or the material being imaged can constitute separate domains, as they result in distinct visual characteristics that may require domain-specific modeling.

In some cases, systems and methods herein can surpass supervised approaches and human annotation in performance across all or substantially all use cases. In some cases, systems and methods herein can learn without labels, thereby enabling continuous adaptation and improvement within a user's specific environment. In a non-limiting example, evaluations on both synthetic and real datasets demonstrate the effectiveness and practical applicability of systems and methods herein.

As a non-limiting example of Deep Learning, ResNet, such as described He, K., et al., “Deep residual learning for image recognition,” in Proceedings of the IEEE conference on computer vision and pattern recognition, 770-778 (2016), which is incorporated by reference herein in its entirety, can use residual learning to enable training of deep CNNs and has become a widely used backbone in specific applications or use cases. Recently, Vision Transformers (ViT), such as those described in Alexey, D., “An image is worth 16×16 words: Transformers for image recognition at scale,” arXiv preprint arXiv: 2010.11929 (2020), which is incorporated by reference herein in its entirety, have leveraged self-attention mechanisms. In some cases, ResNet and ViT-based backbones can achieve sufficient performance in computer vision tasks for specific use cases. However, technical problems remain due to at least a lack of backbones specifically optimized for and generalizable for all or substantially all use cases in semiconductor applications.

In some cases, deep learning-based approaches have marginally implemented object detection and segmentation. As a non-limiting example, Faster-RCNN, such as described in Ren, S., et al., “Faster R-CNN: Towards real-time object detection with region proposal networks,” IEEE transactions on pattern analysis and machine intelligence 39 (6), 1137-1149 (2016), which is incorporated by reference herein in its entirety, introduced Region Proposal Networks (RPN), which can generate region proposals using anchor boxes and region-based pooling. As another non-limiting example, Mask-RCNN, such as described in He, K., et al., “Mask R-CNN,” in ICCV, (2017), which is incorporated by reference herein in its entirety, may extend Faster-RCNN by adding a mask branch for instance segmentation for use as a baseline for pixel-level object localization in some cases.

### Systems and Methods for Metrology and Inspection (MI)

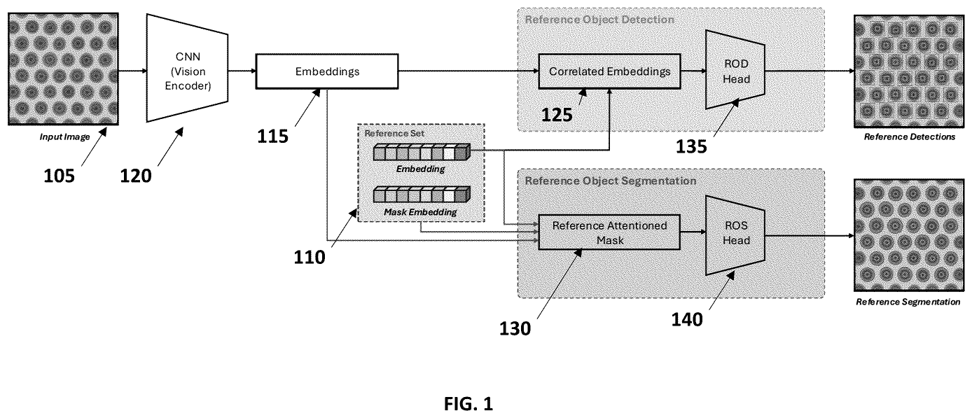

In an aspect, the present disclosure provides at least a technical solution for improved methods in unsupervised detection and segmentation of unknown objects. A non-limiting example of a system architecture diagram for performing the method for unsupervised detection and segmentation of unknown objects is provided in FIG. 1. It will be appreciated that the operations of the method for unsupervised detection and segmentation of unknown object are portrayed sequentially as an illustrative tool only, and these operations may be performed contemporaneously and in any order without departing from the present disclosure.

In some embodiments, the method comprises receiving a first dataset 105 comprising one or more unknown objects, and a second dataset 110 comprising a set of reference embeddings associated with instances of a class of at least one unknown object or the reference objects. In some cases, a class of the unknown object or the reference objects may include one or more of objects patterned on a wafer (e.g., holes, vias, circuits), layers of the patterned wafer, overlays, defects, or test structures.

In some embodiments, the first dataset comprises at least an image of the one or more unknown objects patterned on a wafer using a semiconductor process. In some embodiments, the second dataset comprises at least an image of the one or more unknown objects patterned on a wafer using a semiconductor process. In some embodiments, the first dataset comprises at least an image of the one or more unknown objects obtained using Scanning Electron Microscopy (SEM) or Transmission Electron Microscopy (TEM). In some embodiments, the second dataset comprises at least an image of the one or more unknown object obtained using Scanning Electron Microscopy (SEM) or Transmission Electron Microscopy (TEM).

Some examples of semiconductor processes include photolithography, etching, deposition, ion implantation, doping, oxidation, and packaging. During such semiconductor processes, examples of objects patterned on a wafer can include circuitry and transistors, as well as defects such as impurities and contamination, misaligned components, layer thickness variation, surface roughness, and crystal defects.

In some embodiments, the method comprises generating a set of input embeddings 115 of the one or more unknown object by applying an encoder 120 to the first dataset. The encoder 120 can convert the dataset comprising the one or more unknown object into a lower-dimensional, continuous space, where similar inputs are represented by nearby vectors of a specified dimension, the input embeddings 115. In some cases, the process of converting the dataset to input embeddings 115 configures the input dataset for processing and manipulation by various models and algorithms, described herein.

Some examples of encoders 120 include autoencoders, embedding encoders, word embedding encoders, object embedding encoders, transformer encoders, and dual encoders. Autoencoders may include undercomplete autoencoders, sparse autoencoders, denoising autoencoders, variational autoencoders, recurrent autoencoders, convolutional autoencoders, and vision autoencoders. In some embodiments, the method further comprises generating the set of input embeddings 115 by using a vision encoder 120 to determine a dimension of the first dataset comprising a number of channels and a size.

In some embodiments, the method comprises generating a set of correlated embeddings 125 of the one or more unknown objects by applying a Convolutional Neural Network (CNN) model to the set of input embeddings 115 and the set of reference embeddings 110, wherein the set of correlated embeddings 125 is used to generate at least a detection overlay of the one or more unknown objects. In some cases, the correlated embeddings 125 provide further context for the relationship between the vectors of the input embeddings 115.

In some cases, the CNN model, described herein, comprises a machine learning model described herein. In some cases, the CNN model, described herein, comprises a pre-trained model. In some cases, the CNN model, described herein, comprises a commercially available pre-trained model (e.g., ResNet, VGGNet, etc.). In some cases, the CNN model, described herein, comprises an in-house-trained model.

In some embodiments, the method further comprises generating the set of correlated embeddings 125 by using a mask region-based CNN (mask-RCNN) model comprising a dynamic anchor model to determine a grid of base anchors of the first dataset 105 or the set of reference objects. In some cases, a mask-RCNN model can perform instance segmentation, identifying and outlining individual objects within dataset, as well as object detection with bounding boxes. In some cases, the mask-RCNN model, described herein, can include any model capable of identifying and outlining objects within a dataset.

In some embodiments, the method comprises generating a set of reference-attentioned embeddings 130 by applying a reference-attentioned model to the set of input embeddings 115 and the set of reference embeddings 110, wherein the set of reference-attentioned embeddings 130 is used to predict at least one of a set of detection characteristics or a set of segmentation characteristics with a confidence score.

In some cases, generating a set of reference-attentioned embeddings can include transforming discrete items in the one or more inputs into continuous numerical representations. In some cases, the continuous numerical representations may include one or more vectors in a vector space. As a non-limiting example, these vectors may capture sematic relationships between items, meaning similar objects will have embedding vectors closer to each other in a vector space. In some cases, this can provide additional context to the trained model.

In some cases, generating a set of reference-attentioned embeddings by applying a reference-attentioned model may include one or more attention mechanisms. In some cases, attention mechanisms can enable a model to selectively focus on specific parts of the input data which may be most relevant to the task or tasks at hand. In some cases, attention mechanisms may assign varying weights to different elements of an input. In some cases, the varying weights may be used, at least in part, to assign one or more reference-attentioned embeddings.

In some cases, the method further comprises generating the instances of the class of the at least one unknown object by applying a set of operations to the first dataset thereby obtaining the second dataset.

In some cases, the method further comprises removing artifacts from the first dataset or the second dataset prior to determining the set of correlated embeddings. In some cases, artifacts may include one or more of missing values, outliers, corrupted data, or image artifacts.

In some cases, the method further comprises an unsupervised learning scheme capable of handling multiple downstream tasks such as Reference Object Detection (ROD) at 135 or Reference Object Segmentation (ROS) at 140. In a non-limiting example of ROD 135, correlated embeddings may be introduced. In some cases, the correlated embeddings may provide effective correlation between reference and input embeddings. In some cases, the reference refers to the one or more embeddings extracted from an instance where one or more objects are intended to be identified. In a non-limiting example of ROS 140, one or more reference-attentioned masks may be employed. As a non-limiting example, a new mask may be generated by attentioning to the mask, one or more reference or input embeddings. In some cases, this approach can enable precise recognition even for unseen domain objects without additional training. For example, the input can include a reference set with a reference mask and its corresponding reference embedding, which is used to define the target object. For the query image, input embeddings can be provided. Methods herein can apply attention between the reference and input embeddings to generate the new mask, which is the predicted mask corresponding to the input image. In some cases, the method may be trained to be robust in generalization tasks. In some cases, the method may be trained to be suitable for specific tasks. As a non-limiting example, the method may be trained to be suitable for the two introduced applications, ROD 135 and ROS 140. In some cases, the training may include using pseudo-images and labels from unlabeled data, based on an empirical understanding of CNN behaviors. In some cases, the ROD 135 and ROS 140 applications may enable the method to serve as a backbone for various downstream applications in MI.

In some embodiments, the method further comprises using an output of the trained ML model in metrology and inspection (MI) in a semiconductor process for characterizing at least a metrology of the one or more unknown objects or a plurality of other objects, patterned by a semiconductor process. In some cases, a metrology may include one or more measurements of critical dimensions of an object, surface roughness, topography, film thickness, defects, refractive index, reflectance, transmittance, absorbance, uniformity, and the like.

### Reference Object Detection

In some embodiments, the method further comprises using an output of the trained ML model in Reference Object Detection (ROD) at 135 in a semiconductor process for determining a set of detection characteristics of the one or more unknown objects or a plurality of other objects patterned by a semiconductor process.

In some cases, ROD at 135 can include detection of one or more reference objects. In contrast to general object detection models, which can only recognize objects seen during training, ROD 135 may enable the detection of unseen objects by utilizing reference embeddings of the target object during inference. In some cases, this domain may share similar objectives with other feature-matching approaches such as Scale-Invariant Feature Transform (SIFT) described in Lowe, D. G., “Distinctive image features from scale-invariant keypoints,” International journal of computer vision 60, 91-110 (2004), which is incorporated by reference herein in its entirety. In some cases, this domain may share similar objective approaches with deep-learning-based feature-matching methods such as SuperGlue described in Sarlin, P.-E. et al., “Superglue: Learning feature matching with graph neural networks,” in Proceedings of the IEEE/CVF conference on computer vision and pattern recognition, 4938-4947 (2020), which is incorporated by reference herein in its entirety. In some cases, for object-level applications, template matching may remain one of a few widely used techniques. In some cases, however, template matching can suffer from low performance and limited applicability. For example, template matching might compare pixel values and consider higher similarity as better matches. However, in practice, even the same object can appear differently due to variations in lighting, pose, and other conditions, making template matching unreliable in real-world scenarios. In MI, ROD can be employed for positioning measurement locations or identifying issues in overall array configurations of a semiconductor structure.

### ROD Head

In some cases, ROD at 135 can include an ROD head, which aims to locate objects using reference embeddings. In one non-limiting example, ROD at 135 can include a Mask-RCNN architecture as the foundation. In some cases, the Mask-RCNN architecture may include an anchor-based Region Proposal Network (RPN). In some cases, the Mask-RCNN architecture can include a region-based RCNN. In some cases, core ideas of systems and methods described herein can be extended to other detection architectures. In some cases, the ROD Head may take as input one or more reference embedding R of size Nᵣ×C×Hᵣ×Wᵣ, where Nᵣ allows for multiple reference objects of the same class. In some cases, Nᵣ may be set to 1. The dimensions Hᵣ and Wᵣ may correspond to the output size of the pooling operation in the RCNN, which we set to 14 to facilitate segmentation tasks. In some cases, the RPN may follow an anchor-based detection approach, and a global average pooling may be applied to the reference embedding to obtain a compressed representation of size Nᵣ×C×1×1. This representation may then be transformed into a correlated embedding E_{RPN} for RPN training:

$${E}_{RPN} ( X , R ) = Concat [ {f}_{1} ( X ) , {f}_{1} ( \frac{1}{HW} {\sum }_{i = 1}^{H} {\sum }_{j = 1}^{W} {R}_{ij} ) ] , \qquad ( 1 )$$

where f₁ is a convolutional block. Furthermore, in some cases of RPN, the anchor generator may be used to gridify object regions (or make a grid of object regions). For certain cases described herein, the size and aspect ratio of the reference object can vary for each instance, which can pose a challenge for such cases of RPN. To address limitations encountered by RON in such cases, a Dynamic Anchor Generator system may be used. In some cases, the Dynamic Anchor Generator can construct base anchors based, at least in part, on the one or more reference objects and then forms a grid accordingly. This approach can enable the model to learn and perform inference in a more generalizable manner, even when object sizes and aspect ratios differ across instances. In some cases, detection in the RCNN can include an element-wise subtraction approach to compute the correlated embedding:

$${E}_{RCNN} ( X , R ) = {f}_{2} ( X ) - {f}_{2} ( R ) \qquad ( 2 )$$

where f₂ is a convolutional block. In some cases, the choice of correlation methods, concatenation in the RPN and element-wise subtraction in the RCNN, may be determined empirically. In one non-limiting example, the RPN utilizes a 1×1 feature representation. In the non-limiting example, concatenation can enrich feature information. In contrast to some RPN systems, the RCNN may benefit from computing differences between individual features, leading to improved performance in some cases. In some embodiments, each set of detection characteristics comprises at least one of (i) a set of positioning measurement locations of the one or more unknown objects or the plurality of objects or (ii) an issue in a hierarchical structure comprising the one or more unknown objects, patterned by the semiconductor process.

### Reference Object Segmentation

In some embodiments, the method further comprises using an output of the trained ML model in Reference Object Segmentation (ROS) 140 in a semiconductor process for determining a set of segmentation characteristics of the one or more unknown objects or a plurality of other objects patterned by a semiconductor process.

In some cases, Reference Object Segmentation (ROS) at 140 can extend the concept of ROD 135 to segmentation tasks. In contrast to some general object segmentation models, which may only recognize seen objects from the training phase, ROS 140 can allow for the segmentation of unseen reference objects. In some cases, ROS 140 can enable detection of unseen reference objects when a mask is provided at inference time. As a non-limiting example, ROS can be utilized to measure the multiple similar structures such as those found in MI applications.

### ROS Head

In some cases, ROS at 140 can include a ROS head which performs segmentation on the candidate regions obtained through the ROD Head. In a non-limiting example, embeddings extracted from the input image may be denoted as E_{MASK-RCNN} of size N_{C}×C×Hₚ×Wₚ, and the reference object's embedding may be denoted as R of size Nᵣ×C×Hₚ×Wₚ, and its corresponding mask information may be denoted as M of size Nᵣ×1×Hᵣ×Wᵣ. In one non-limiting example, the Mask Encoder, g_{ME}, is composed of convolution, layer normalization, and GELU activation layers. In some examples,

$${g}_{ME}^{k}$$

can increase the number of channels by a factor of 32 while reducing the width and height by a factor of 16, producing an embedding output. In some cases, the example further comprises setting R and M of size Nᵣ×C×Hₚ×Wₚ as the key and value, respectively, while E_{MASK-RCNN} serves as the query. In such cases, a multi-head attention may then be applied across blocks to compute a low resolution reference-attentioned mask,

$${P}_{MASK}^{1 / 16} :$$

$${P}_{MASK}^{1 / 16} = Attention ( {E}_{MASK - RCNN} , R , {M}^{1} ) , \qquad ( 3 )$$

where

$${M}^{1} = {g}_{ME}^{1} ( M ) .$$

Next, E_{MASK-RCNN}, R are upsampled using an Upscaler Block by a factor of 2. In some cases, the same process may be repeated to have a high resolution reference-attentioned mask using

$${g}_{ME}^{2} :$$

$${P}_{MASK}^{1 / 8} = Attention ( {E}_{MASK - RCNN}^{2} , {R}^{2} , {M}^{2} ) . \qquad ( 4 )$$

where

$${M}^{2} = {g}_{ME}^{2} ( M ) .$$

In some cases, the enriched reference-attentioned mask may be obtained by concatenating the upsampled lower-resolution reference-attentioned mask with the higher-resolution reference-attentioned mask:

$${P}_{MASK}^{′} = Concat ( {P}_{MASK}^{1 / 8} , Upscaler ( {P}_{MASK}^{1 / 16} ) ) . \qquad ( 5 )$$

In some cases, the final mask map may be predicted by stacking three upscaler blocks and a single convolution layer:

$${P}_{MASK} = Conv ( {Upsampler}^{3} ( {P}_{MASK}^{′} ) ) . \qquad ( 6 )$$

In some cases, where the method comprises Mask-RCNN, the same training objectives and loss functions may be utilized as Mask-RCNN. In some cases, the attention-based mask-building process can provide significant advantages in terms of generalization ability.

In some embodiments, each set of segmentation characteristics comprises at least a metrology of the one or more unknown objects or the plurality of other objects, patterned by the semiconductor process.

### SiliconBASE

In one non-limiting example, systems and methods herein provide an architecture (or SiliconBASE architecture) designed for various downstream applications in the semiconductor field. In some cases, SiliconBASE can be integrated with various backbone networks, enabling its use in object detection, segmentation, or as a new baseline model for fine-tuning.

In some cases, SiliconBASE performs embedding-based object detection and segmentation. In one non-limiting example, embeddings may be extracted through a vision encoder. In one non-limiting implementation, ResNet-18 may be used as the vision encoder. In other non-limiting implementations, other networks such as ResNet-50, described herein or Vision Transformer, described herein, can also be employed. In one non-limiting example, an input image may be provided where the extracted embeddings X have a dimension of 1×C×H×W, and where C represents the number of channels in the vision encoder's output, and H and W denote the height and width of the embedding, respectively, represented as a grid.

In some embodiments, the method further comprises generating a set of reference-attentioned embeddings by using a multi-head attention model to obtain a low-resolution reference-attentioned mask and a high-resolution reference-attentioned mask.

In some cases, the multi-head attention model comprises a ROD head described herein, a ROS head described herein, or both.

In some embodiments, the detection overlay or the segmentation overlay is embedded with data associated with a class of the at least one unknown object, a confidence score of the class, a label of the at least one unknown object, a confidence score of the label, an identification of the at least one unknown object, or a confidence score of the identification.

In some embodiments, the method further comprises predicting, by the trained ML model, at least one of (i) a set of detection characteristics of the one or more unknown objects or (ii) a set of detection characteristics of other objects of the same class. In some embodiments, each set of detection characteristics comprises at least a location of the one or more unknown objects or locations of the other objects, patterned on a wafer using a semiconductor process.

In some embodiments, the method further comprises predicting by the trained ML model, at least one of (i) a set of segmentation characteristics of the one or more unknown objects or (ii) a set of segmentation characteristics of other objects of the same class. In some embodiments, each set of segmentation characteristics comprises at least metrology measurements of the one or more unknown objects or metrology measurements of the other objects, patterned on a wafer using a semiconductor process.

### Data Preparation

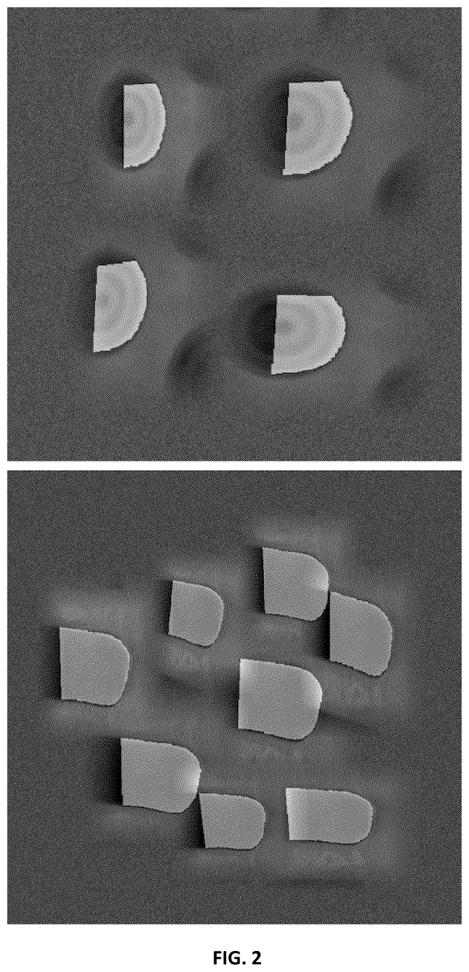

In some cases, labeled training data may be generated by extracting random object-like patches from unlabeled datasets, applying various augmentations, and arranging them in repeated patterns. A non-limiting example of labeled training data is provided in FIG. 2. In some cases, a goal in the generation of labeled training data is to create diverse variations to enhance the robustness of detection and segmentation models. In some cases, such patch cropping methods can introduce artifacts, such as artificial borders at the cropped regions, which may cause the model to learn these artifacts rather than the actual object features. To mitigate this issue, data generation process employed in systems and methods herein may follow a structured approach.

### Data Generation Method

In some cases, data generation can include selecting a positive image, which contains semiconductor-related measurement objects, and a negative image, which is used to extract background characteristics. In some cases, to increase diversity. one or more resizing and flipping augmentations may be applied to the positive image. In some cases, background image may be generated by computing the mean values of the negative image with noise addition and blur. In some cases, a positive template patch may be extracted from the positive image if its gradient distribution exceeds a predefined threshold. For example, thresholds can be determined empirically and may vary depending on the overall characteristics of the image. Gradient distribution can represent a form of edgeness in the image. A threshold can be applied to this edgeness to help determine the presence of an object. If the edgeness exceeds the threshold, the region can be defined as a potential object. Typical values can depend on image contrast and noise levels and adjusted or optimized accordingly.

The mask ground truth and bounding box may be obtained by selecting the largest component's contour within the patch. Since, in some cases, where the object region may not be influenced by artificial borders introduced during cropping, the inner region of the patch is considered valid. In some cases, to gradually reduce border effects while maintaining diversity, a weight map is generated using a distance transform approach. In one non-limiting example, the base template may be defined as a set consisting of the object patch, mask ground truth, bounding box ground truth, or weight map. The base template may be repeatedly augmented and attached onto the background image one at a time. Augmentations such as noise addition, aspect ratio adjustment, and resizing may be implemented in determining the generalization ability of the detection and segmentation model under varying conditions.

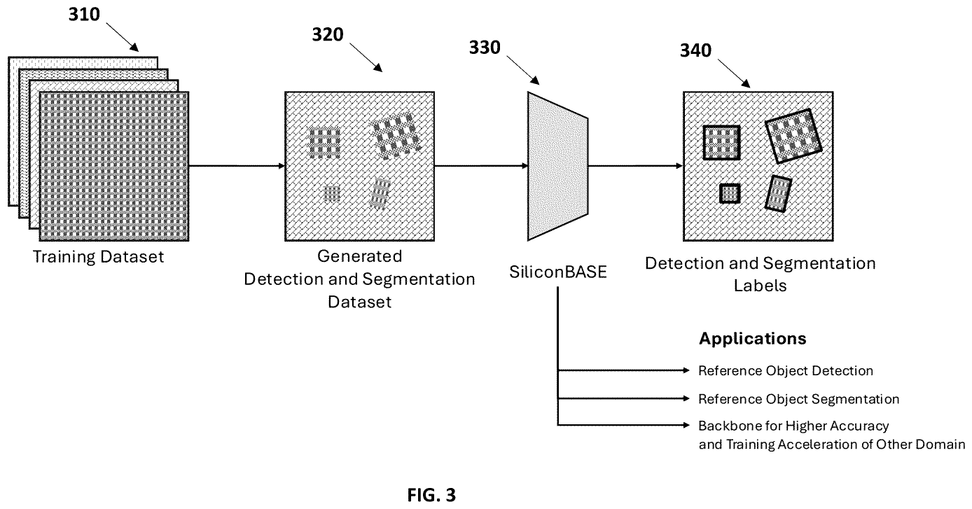

A non-limiting example of data preparation and data generation is provided in FIG. 3, in accordance with some embodiments. In the non-limiting example, a training dataset may be provided at 310, which may be transformed at 320 into a detection and segmentation dataset using one or more augmentations. In some cases, the detection and segmentation dataset may be used as an input for a trained ML model at 330, such as, for instance, SiliconBASE, described herein. In some cases, this input may be transformed at 330 to yield detection and segmentation labels at 340.

In some embodiments, the trained ML model is trained using reference-based training on the first dataset or the second dataset. In some embodiments, the trained ML model is validated by determining (i) a difference between the detection overlay and a detection overlay determined by domain expertise or (ii) a difference between the segmentation overlay and a segmentation overlay determined by domain expertise. In some cases, differences between overlays can include comparative distance of the embedding vectors in the vector space or differences in confidence score for an unknown object.

In some embodiments, the method further comprises repeating the method until determining the detection overlay or the segmentation overlay for all unknown objects or substantially all unknown objects of the first dataset. In some embodiments, the accuracy of the trained ML model is determined using average precision (AP), average recall, or mean intersection over the union (IOU). In some embodiments, the accuracy is at least 90%.

In some embodiments, the method further comprises using an output of the trained ML model to determine or predict an anomaly in an unknown object patterned on a wafer using a semiconductor process. In some cases, anomalies may include one or more of defects, chemical defects, pattern deformations, scratches or cracks, surface roughness, incomplete layers, or any other defect in the desired structure of the semiconductor.

In some embodiments, the method further comprises using an output of the trained ML model to search for an unknown object patterned on a wafer using a semiconductor process. In some cases, an output of the trained ML model can be used in image-based search and anomaly detection.

In some cases, the approach of systems and methods herein may enable users to obtain a backbone model suited to their environment while supporting core MI applications such as object detection and segmentation. In some cases, leveraging the backbone network may require fewer images to efficiently train models for downstream tasks. As a non-limiting example, experiments using a sample architecture, provided below, demonstrate a high performance and generalization ability in some cases. In some cases, systems and methods herein may be applicable in a number of additional downstream tasks.

### EXAMPLES

While various examples of the present disclosure are shown and described herein, such examples are provided by way of example only. Numerous variations, changes, or substitutions may occur without departing from the present disclosure. It should be understood that various alternatives to the examples described herein may be employed.

In some cases, systems and methods for semiconductor metrology and inspection applications described herein can include use of a computer program product. In some cases, systems and methods for semiconductor metrology and inspection applications described herein can include use of a computer program product for SEM and TEM data measurement and analysis. In some cases, the computer program product may include SiliconBASE: Multi-Task Baseline Model for Semiconductor Metrology and Inspection Applications.

### Example 1—Experimental Validation of a Sample Trained ML Model

In one non-limiting example, a sample model is provided comprising a Feature Pyramid Network (FPN) architecture, such as described in Lin, T.-Y. et al., “Feature pyramid networks for object detection,” in Proceedings of the IEEE conference on computer vision and pattern recognition, 2117-2125 (2017), which is incorporated by reference herein in its entirety. The sample model further includes a ResNet-18network backbone, such as described in He, K., et al., “Deep residual learning for image recognition,” in Proceedings of the IEEE conference on computer vision and pattern recognition, 770-778 (2016), which is incorporated by reference herein in its entirety. Depending on the scale of the training data and the target performance, alternative backbones such as ResNet-101 or Transformer-based networks, such as those described in Vaswani, A., “Attention is all you need,” Advances in Neural Information Processing Systems (2017), which is incorporated by reference herein in its entirety, can also be employed. For feature extraction, the first three stages of the ResNet backbone may be utilized to construct the FPN. In one example, the first stage corresponds to the earliest convolutional layer, which has the highest spatial resolution. The model may be optimized using the AdamW optimizer with an initial learning rate of 0.0001 and a weight decay of 0.0005. In the example, the learning rate can follow a step decay schedule with a step size of 256 and a decay factor of 0.3333. In the example, the training process spans 1024 epochs. In some cases, the sample model can include a lightweight backbone and can operate with high speed and minimal memory usage in certain applications. In the example, the sample model is trained and evaluated using a single T4 GPU. In the non-limiting example, 57 distinct semiconductor images may be utilized as the source training dataset.

### Evaluation

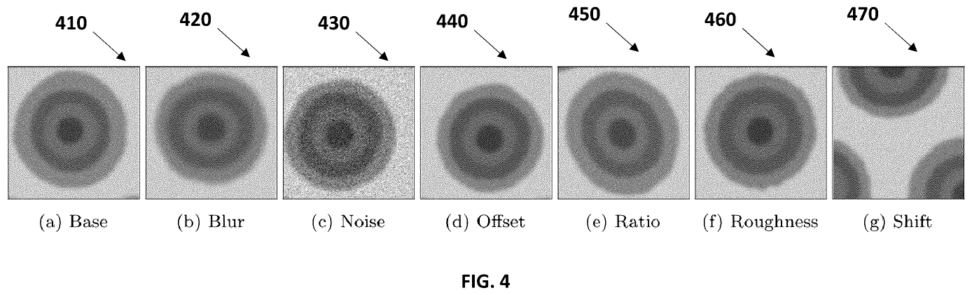

To reflect various challenging real-world conditions, an evaluation dataset may be constructed for object detection and segmentation on semiconductor images, incorporating seven representative variation types. A non-limiting example of variation types is provided in FIG. 4. In the non-limiting example, variations may include Basic 410 Blur 420, Noise 430, Offset 440, Ratio 450, Roughness 460, and Shift 470 FIG. 4. For each variation, 10 images may be included, which can result in a total of 70 evaluation images in some cases. Each image can contain numerous multi-layer objects, providing a comprehensive assessment of model robustness under diverse perturbations.

In the non-limiting example, the model may be validated using the metrics adopted in the COCO benchmark, such as those described in Lin, T.-Y., et al., “Microsoft coco: Common objects in context,” in ECCV, (2014), which is incorporated by reference herein in its entirety. In some cases, metrics can include Average Precision (AP) and Average Recall (AR), as well as mean Intersection over Union (mIoU) for semantic segmentation. These metrics can provide a standardized evaluation framework. In some cases, these metrics may be used to ensure comparability with models following COCO-style benchmarks. As background, AP and AP₅₀ are standard in the COCO evaluation protocol. AP₅₀ indicates that an object is considered correctly detected if the Intersection over Union (IoU) with the ground truth is at least 50%. AP (Average Precision) is computed by averaging precision across multiple IoU thresholds, typically from 50% to 95% in 5% increments. These metrics evaluate both the accuracy of object localization and classification and offer a more comprehensive comparison than simple percentage-point accuracy.

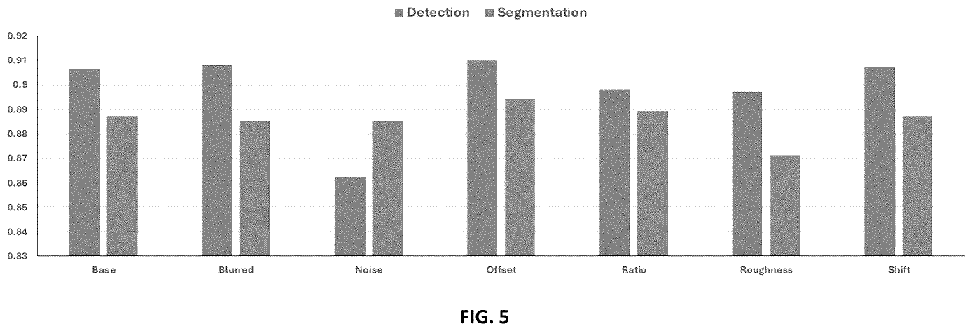

In some cases, the area under the precision-recall curve and is reported as AP, AP₅₀, and AP₇₅. Here, AP is the mean precision computed over multiple IoU thresholds from 0.5 to 0.95 with a step size of 0.05. AP₅₀ and AP₇₅ represent the AP values at fixed IoU thresholds of 0.50 and 0.75, respectively. A non-limiting example of AP is provided in FIG. 5 for the seven representative variation types, described herein.

In some cases, the mean recall across multiple IoU thresholds may be computed, providing insight into how well the model detects objects at various confidence levels.

In some cases, the mean intersection over union may be used for evaluating semantic segmentation performance. In some cases, mean intersection over the union measures the average IoU across all classes, quantifying the overlap between predicted segmentation masks and ground truth annotations.

In some cases, the model may be trained using unsupervised learning on a separate dataset that does not include the evaluation dataset. For evaluation, the first image of the base type in the evaluation dataset may be used as the reference image, while the remaining 69 images may be assessed as unseen domains. For Mask-RCNN, the model may be fine-tuned using the first image of the base type as a pretrained reference and evaluated on the remaining 69 images as seen domains. In a non-limiting example of evaluation, the trained model can detect and recognize four holes using a single model. In contrast, Mask-RCNN may be evaluated in two settings: (1) a single model trained on the base-type image, and (2) four separate models, each trained independently on different hole types. In some cases, the trained model is evaluated for both object detection and segmentation, incorporating experiments on various variation types, visualizations, and comparisons with human annotations.

In a non-limiting example of object detection, the trained model may be compared with Template Matching, which can operate under the similar unsupervised conditions, and Mask-RCNN trained on a single image. In this non-limiting example, using the same conditions for each model, the trained model may outperform Template Matching by 0.182 percentage points (pp) in AP and 0.187 pp in AR, in some cases. In this non-limiting example, the trained model may be compared to Mask-RCNN using two configurations. In the first setup, a single model may be trained on four hole instances. In some cases, this approach can struggle with detecting fully overlapping objects, resulting in significantly low performance. In some cases, this may be addressed by training four separate Mask-RCNN models, each handling a single instance. Even in this such a case, the trained model can outperform Mask-RCNN by 0.179 pp in AP and 0.181 pp in AR, in one non-limiting example. In some cases, Mask-RCNN may demonstrate adequate performance at an IoU threshold of 50; However, the performance gap can grow at higher IoU criteria.

In some cases, directly comparable unsupervised methods may not be available. As a non-limiting example, the trained model may be evaluated against Mask-RCNN trained on a single image. Similar to object detection, the single Mask-RCNN model can struggle to distinguish multi-layered objects, in some cases. In a non-limiting example, the trained model can provide an advantage compared to the four separate Mask-RCNN models, achieving a 0.151 pp improvement in AP, 0.154 pp in AR, and a 0.102 pp difference in mIoU. For example using 0.151 pp, it can be interpreted as an average improvement of 15.1 percentage points in accuracy across the full range of IoU thresholds. I the previous method detected 70 out of 100 objects, the current method can detect approximately 85, reflecting a substantial gain in overall detection performance.

In some cases, the trained model may be compared against human annotation. As a non-limiting example, a single image of each variation type may be selected and manually annotated. In some cases, this may include up to approximately 1,000 hole instances. The results of the human annotation may then be compared to those obtained using the trained model. The trained model may demonstrate improved performance in both detection and segmentation, in some cases. This outcome may be attributed to the potential inaccuracy of human annotations at very fine scales. In some cases, the trained model may demonstrate comparable performance to human annotation.

TABLE 1

| | Learning | | Detection | | | |
|---|---|---|---|---|---|---|
| Method | Train | #Model | AP | AP₅₀ | AP₇₅ | AR |
| Template Matching | — | 1 | 0.709 | 0.819 | 0.777 | 0.738 |
| Ours | — | 1 | 0.891 | 0.990 | 0.990 | 0.925 |
| Mask-RCN [symbol] | ✓ | 1 | 0.322 | 0.432 | 0.388 | 0.344 |
| Mask-RCN [symbol] | ✓ | 4 | 0.712 | 0.874 | 0.831 | 0.744 |
| Ours^{†} | — | 1 | 0.897 | 1.000 | 1.000 | 0.925 |
| Human^{†} | — | 1 | 0.854 | 1.000 | 0.959 | 0.889 |

Table 1 provides a non-limiting example of evaluation of detection on datasets with 4 hole classes and 7 difficulty levels. The symbol † marks results from a subset (1,175 hole instances) of the full dataset with human annotation.

TABLE 2

| | Learning | | Segmentation | | | | |
|---|---|---|---|---|---|---|---|
| Method | Train | #Model | AP | AP₅₀ | AP₇₅ | AR | mIoU |
| Ours | — | 1 | 0.878 | 0.990 | 0.990 | 0.910 | 0.932 |
| Mask-RCN [symbol] | ✓ | 1 | 0.338 | 0.435 | 0.397 | 0.354 | 0.361 |
| Mask-RCN [symbol] | ✓ | 4 | 0.727 | 0.874 | 0.844 | 0.756 | 0.830 |
| Ours^{†} | — | 1 | 0.889 | 1.000 | 1.000 | 0.913 | 0.931 |
| Human^{†} | — | 1 | 0.870 | 1.000 | 0.986 | 0.894 | 0.913 |

Table 2 provides a non-limiting example of evaluation of segmentation on datasets with 4 hole classes and 7 difficulty levels. The symbol †marks results from a subset (1,175 hole instances) of the full dataset with human annotation.

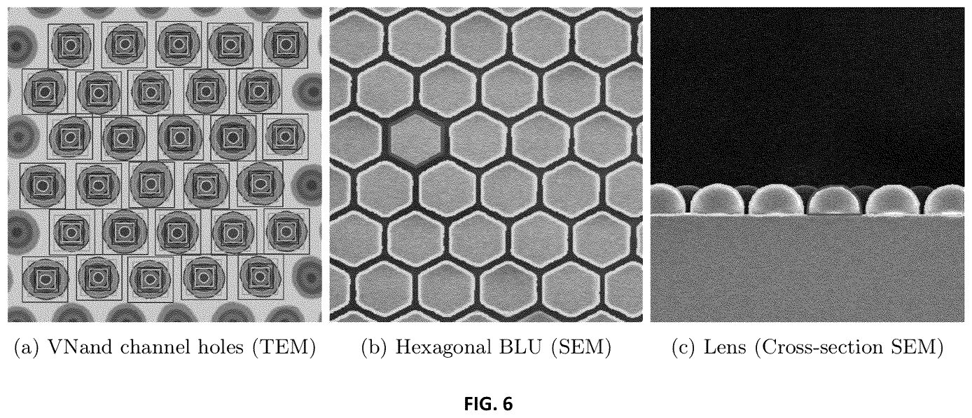

In some cases, the trained model may be evaluated across diverse environments. In one non-limiting example of evaluation, experiments may be conducted on a synthesized dataset, such as those provided in Table 2. In some cases, a synthesized dataset may be chosen to reflect various real-world challenges, such as structural complexity, noise, and scale ratio offsets. In another non-limiting example, the trained model may be evaluated on various real-world microscopy images, including memory and lens of SEM and TEM, to show its generalization ability. A non-limiting example of real-world microscopy images is provided in FIG. 6. In some cases, the model may be evaluated on reference object detection and segmentation. In some cases, there are no direct comparative methods to the trained model. In a non-limiting example, the trained model may be evaluated against a supervised Mask-RCNN9 model. To show the challenge of distinguishing ambiguous layer boundaries, an output of the trained model may also be compared with human annotations. In some cases, the trained model may outperform both supervised methods and human annotation. In some cases, Mask-RCNN can struggle with overlapping objects due to their proximity, resulting in significantly reduced performance when using a single model. To address this challenge, four separate models may be used in some cases. In some cases, the trained model can exhibit high accuracy even on unseen images and supports various downstream applications. In some cases, the trained model may include a high-performance, lightweight model that can be directly applied as a baseline in practical applications.

In some cases, the trained model may operate robustly across various types of data. The presented results provide a non-limiting example of how the model performs across entire images when only a single object within an image is designated as a reference. In some cases, images used in evaluation are not used during training and belong to entirely different domains.

### Example 2—User Workflows Using Systems and Methods Herein

Provided herein is an example of a user workflow for a computer program product of systems and methods for semiconductor metrology and inspection applications, described herein. It will be understood the example of a user workflow described herein is illustrative and not limitative in scope. Numerous variations, changes, or substitutions may occur without departing from the present disclosure.

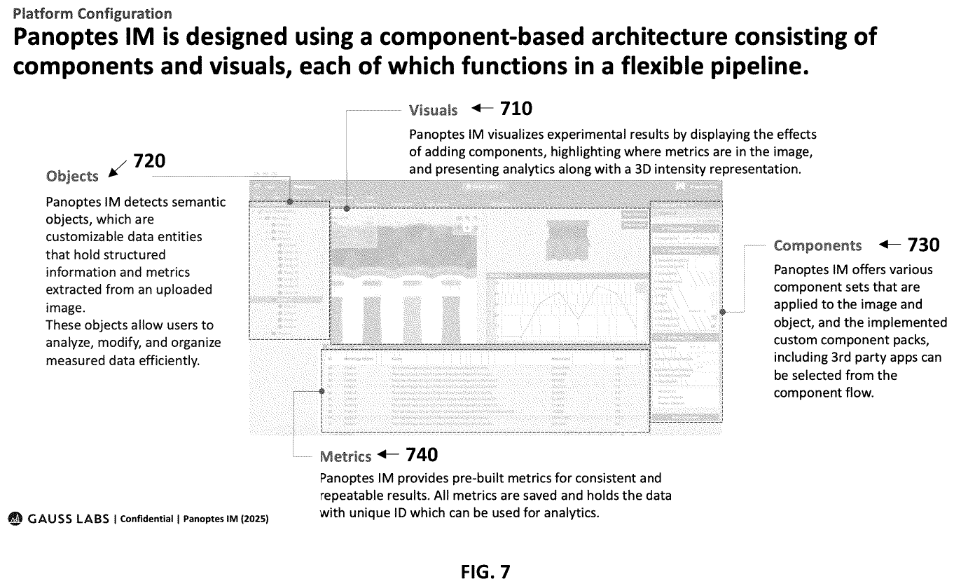

A non-limiting example of a user workflow for a computer program product of systems and methods for semiconductor metrology and inspection applications is provided in FIG. 7. In some cases, the user workflow includes one or more visuals 710 for visualizing experimental results. In some cases, the visuals 710 can display one or more of effects of adding components, highlighting where metrics are in the image, or presenting analytics along with the 2D intensity representation. In some cases, the user workflow includes or more objects 720. In some cases, the objects 720 can include customizable data entities which can hold structured information and metrics extracted from an uploaded image. In some cases, the objects 720 can allow users to analyze, modify, and organize measured data efficiently. In some cases, the user workflow includes one or more component sets 730 which may be applied to one or more of objects 720. In some cases, the one or more component sets 730 can include custom applications, third party applications, or both. In some cases, the user workflow includes one or more metrics 740 which can enable consistent and repeatable results. In some cases, the metrics 740 may be saved with a unique identifier which may be used for analytics.

### Semantic Metrology

In some examples, the user workflow for a computer program product of systems and methods for semiconductor metrology and inspection applications, described herein, can use semantic metrology. In some examples, the semantic metrology further includes one or more semantic objects. In some examples, semantic objects may include at least the following characteristics: customizable structure, hierarchical organization, and integration with metrology tools.

As an example, a semantic object may be a customizable structure. A semantic object may be metadata and measurement metrics extracted from an image. A semantic object may be a user input for measurement, description of properties, and hierarchical relationships among a set of semantic objects. Each of the measurement, properties, and hierarchical relationships among a set of semantic objects may be configured to be customizable by the user.

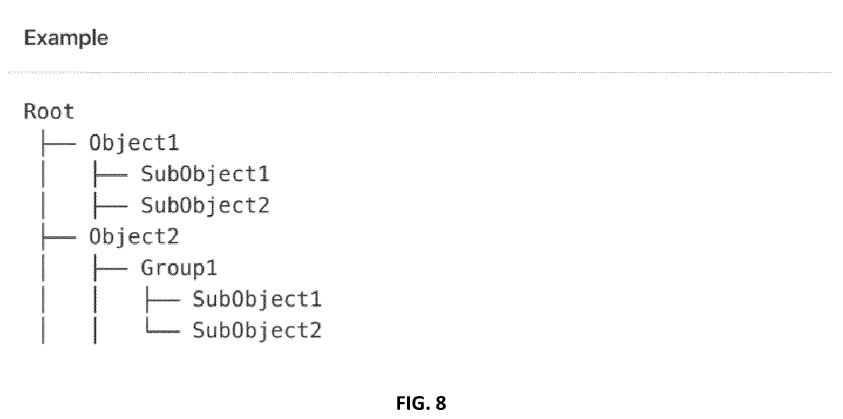

As an example, a semantic object may be a hierarchical organization. An example of a hierarchical organization is shown in FIG. 8. A set of semantic objects may be structured in a parent-child relationship, allowing child objects to inherit or extend attributes from parent objects. A semantic object may contain sub objects, allowing a continuously nestable structure. Each object in a set of semantic objects may be a component flow, or a set of components that are applied to an object, which describes how the object may be measured.

### Component Flow

As an example, a semantic object may include seamless integration with component-based analysis tools. Seamless integration with component-based analysis tools may include attaching image processing components, applying filters, extracting refined data, etc.

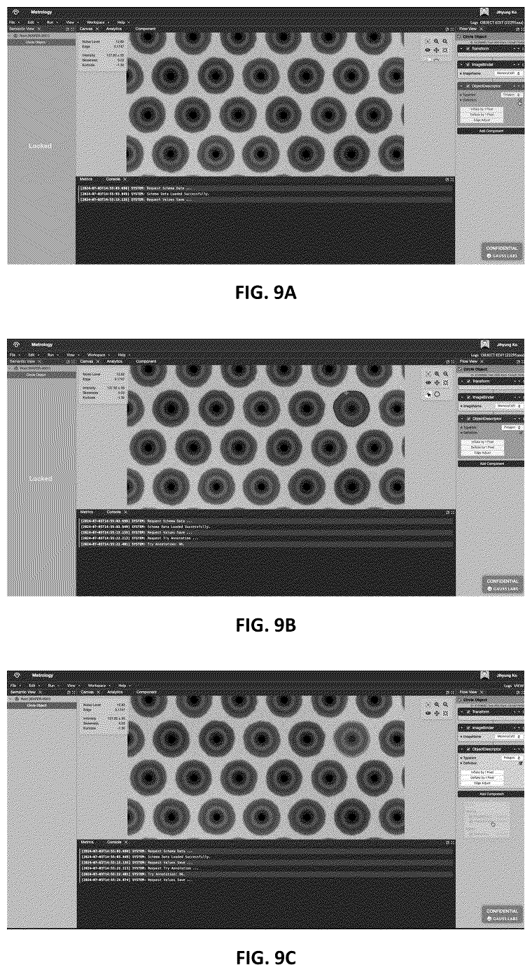

Each semantic object, as described herein, may be a component flow. A component flow is a set of one or more components applied to an object which describes how the object may be measured. An example of a component flow is provided in FIGS. 9A-9C. To start, the user may identify the object they want to manipulate FIG. 9A. Then, the user may select the target object from the dataset FIG. 9B. Once the object is selected, the user may add the Image Source component FIG. 9C, which is responsible for loading the image associated with the object.

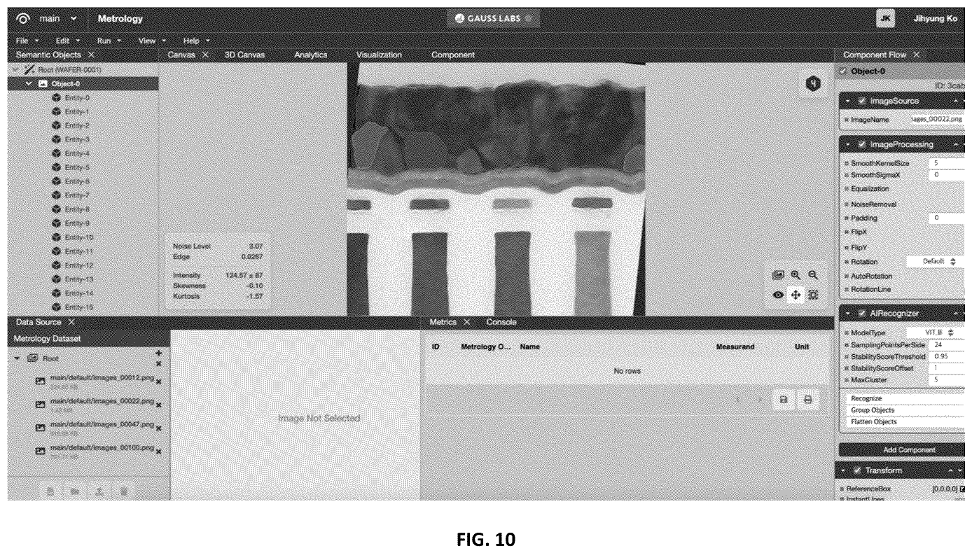

In some examples, the component flow may further include processing components. An example of processing components is provided in FIG. 10. To start, the user may select one or more processing components, such as ImagePreprocess to apply preprocessing operations such as filtering and noise reduction, or AIRecognizer to automatically extract patterns from the image. The user may continue to add processing components to customize the workflow to their needs. Once all options have been selected, the metrology is set up and may be run by clicking Run Metrology to obtain metrics. It is worth noting, each object in a set of objects may have different components assigned, making the workflow flexible and customizable.

### Starting Workflows

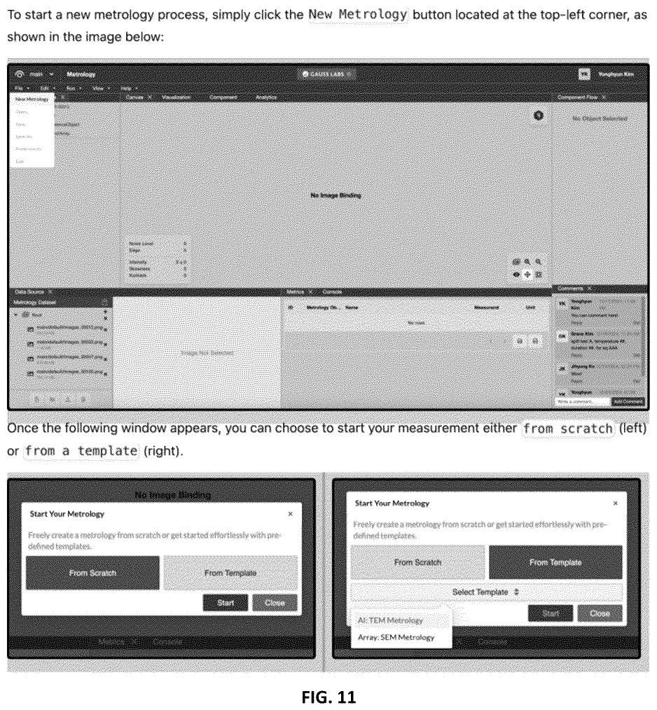

In some examples, users may freely start measurements either from scratch or by using predefined templates, enabling quick measurement setup with just a few clicks. An example of a new metrology process is shown in FIG. 11. To start, the user may simply click the New Metrology button. The user may then choose to start their measurement From Scratch or From Template.

### Viewing and Analyzing Extracted Metrics

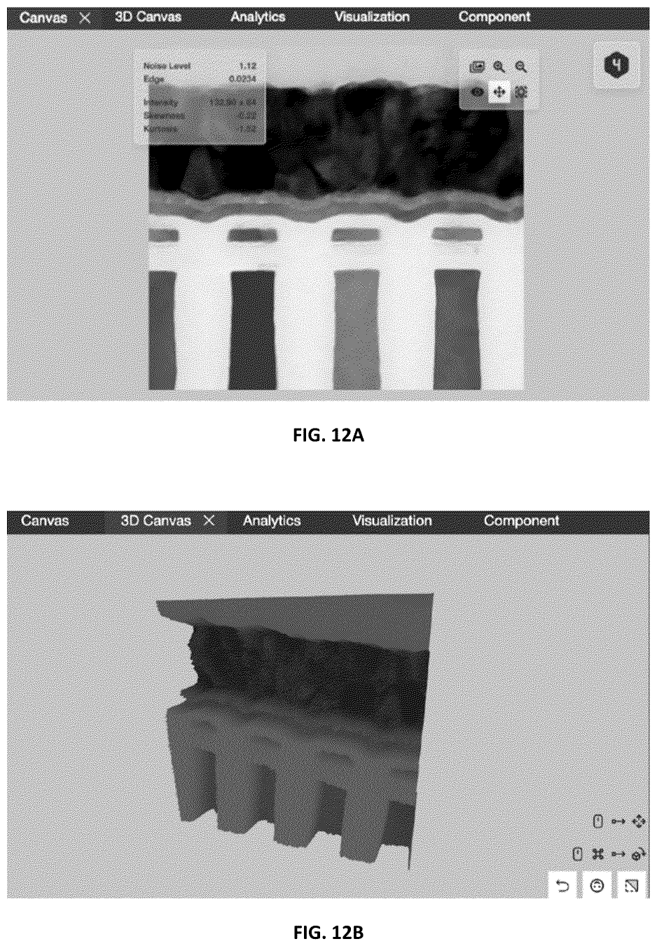

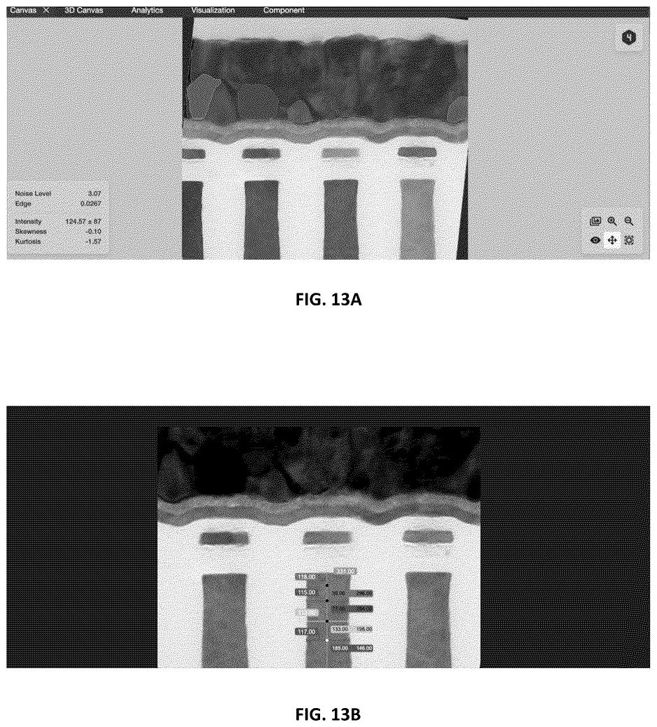

In some examples, users may view the extracted metrics after running a metrology process from scratch or from a template. Extracted metrics may be viewed in the Metrics tab. Metrics may be viewed in the Canvas. An example of the Canvas is shown in FIGS. 12A-12B. An example of a Canvas may be a 2D Canvas FIG. 12A or a 3D Canvas FIG. 12B. The Canvas allows users to visualize metric information extracted form an image. Additionally, if an object is extracted in the Canvas, users may perform additional actions such as setting the coordinates of the object or viewing the position with a color overlay. An example of a color overlay is shown in FIG. 13A. An example of a metric overlay is shown in FIG. 13B.

In some examples, data may be analyzed using the powerful built-in Analytic Tool. In some cases, this analysis may include adjusting and analyzing values, allowing the user to determine the optimal measurement methods in real time. In some examples, the analysis may include querying metrics using the Query tool. The Query tool allows users to fill in keywords and includes auto-suggestions. Using the tab key populates suggested keywords. The user may use the dot (.) notation to navigate sub-elements. All sub-elements may be selected using the asterisk (*). An example query can be Root.circlePatterns.*.*.DiameterX. The Query tool also supports function capabilities, enabling operations between metrics. An example of a Power Spectral Density (PSD) function applied to an example query can be PSD (Root.circlePatterns.*.*.DiameterX). Additionally, the Query tool supports correlation metrics, such as R-squared (RSQ), Root Mean Square Error (RMSE), and Mean Difference.

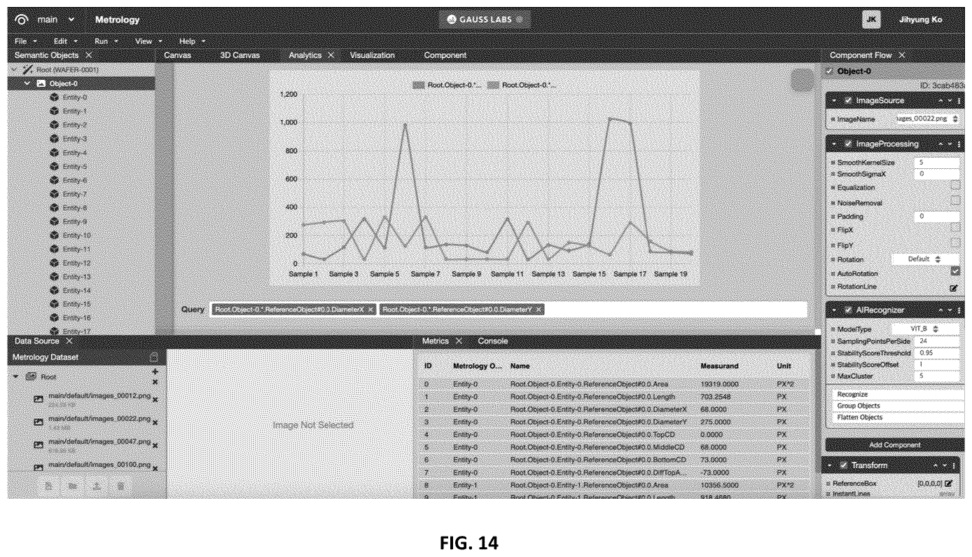

In some examples, multiple queries may be displayed at one time. In some examples, one or more queries may be displayed to a user. An example of a multi-query graph is shown in FIG. 14.

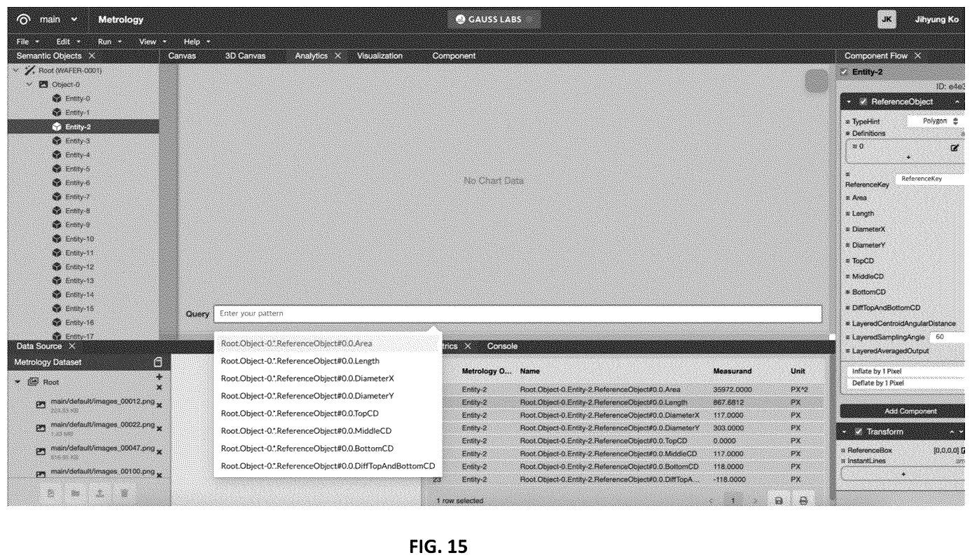

In some examples, analysis may further include the Chart Suggestion feature to provide recommendations for queries. In some examples, the Chart Suggestion feature automatically suggests charts when there are repeating elements above a minimum threshold. These suggestions may help the user to quickly analyze data without needing to construct queries manually. An example of Chart Suggestions is shown in FIG. 15.

In some examples, the user may create custom components and add metrics for analysis. Once a metric is added, it may be analyzed using queries in the analysis graph. In some cases, custom metrics may provide more flexibility in analysis and help extract insights specific to the user's needs.

### Component Packs

In some examples, the user workflow for a computer program product of systems and methods for semiconductor metrology and inspection applications, described herein, can include one or more Component Packs. A Component Pack is a package which may contain single or multiple components. For example, a Component Pack may include Denoiser, ImageEnhance, CustomMetric, and MetricNameChanger functionalities. Component Packs allow the user to manage and modify various components that handle image processing and some related tasks. Additionally, the user can add custom component packs to implement their own functionalities.

In some examples, the user may create a component pack by clicking the Create button in the Component Pack list. Then, the user may select whether to create a Single Component Pack or a Multiple Component Pack. Once chosen, the user will be prompted to choose a template based on the component type. Each template provides a basic code structure. The user will then fill in the Component Pack details, including the Name, Names of components, Description (optional) and Filename for an entryFile (optional). A README will automatically be created, which the user may modify. If the user already has a README file, they may upload it instead. The same is true for the FEATURE and CHANGELOG files. Once this is completed, clicking Add Pack will create the Component Pack.

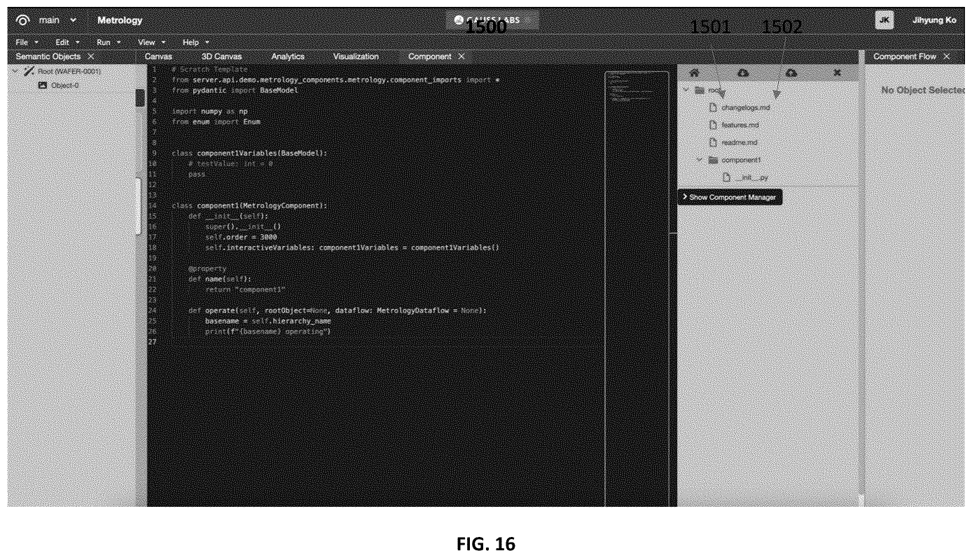

Once the Component Pack is created, the user will be re-directed to the code editor. Here, the user can input the code for their custom Component Pack and upload it to complete the component creation process. An example of the code editor window 1600 is shown in FIG. 16.

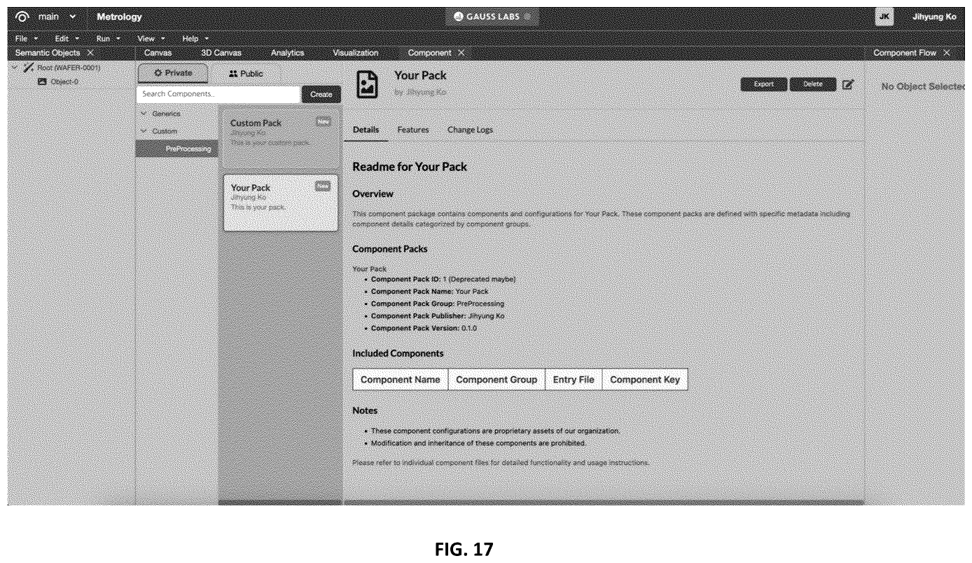

The user may also edit an existing Component Pack. To edit a Component Pack, the user will navigate to the Component Pack List and click on the Component Pack card containing the Component Pack they wish to edit. Then, in the details window, the user will click the edit icon. An example of the details window is shown in FIG. 17. To save any changes, the user may click the cloud upload button 1601 in the code editor 1600. To discard any changes, the user may click the cloud reload button 1602 in the code editor 1600.

The user may configure whether a Component Pack may be shared with workspace members or remain for private use only. This allows the user to privately test a component before sharing with their team. When a new Component Pack is created, it is set to private by default. To share with workspace members, the user may change the status to public, and share using Export. Public Component Packs may also be imported using Import. These imported Component Packs may then be duplicated, and their status may be changed back to private for future private testing.

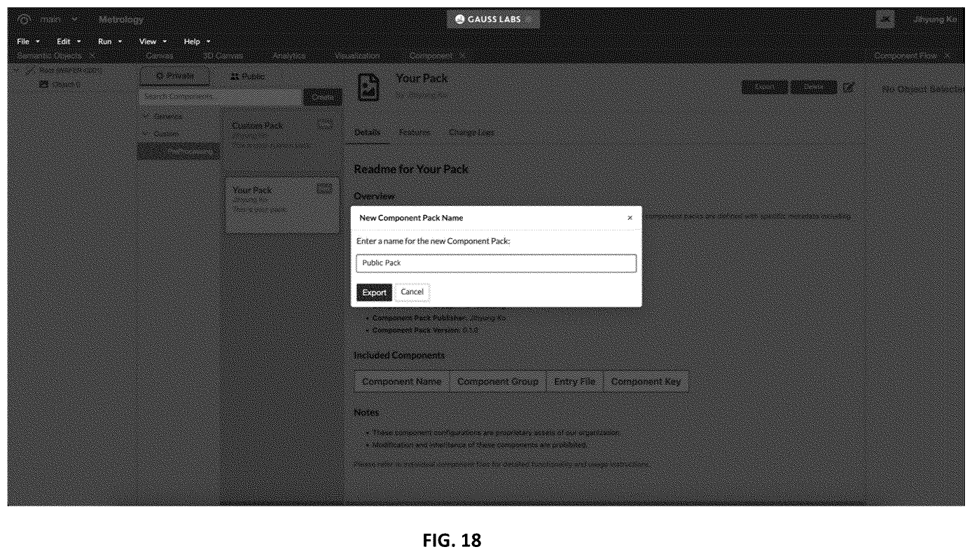

Private Component Packs may also be exported by a user. To export a private Component Pack, the user may open the private Component Pack's detail page and press the Export button. This will create a public version of the private Component Pack and prompt the user to name the new version. The shareable, duplicated public Component Pack will then be created with the same content, which is available for export and import. An example of a duplicated public Component Pack is shown in FIG. 18.

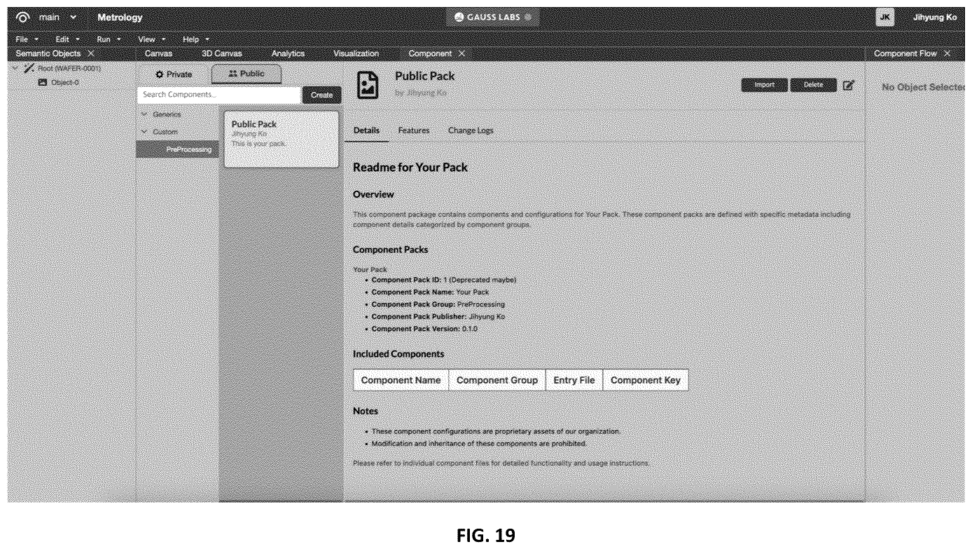

All public Component Packs are available for download by a user. To view the public Component Packs, a user may click on the Public tab. Here, a user may find Component Packs to download or check their duplicated public Component Pack has been successfully published. An example of a list of available public Component Packs in the Public tab is shown in FIG. 19.

### Computing Systems

In another aspect, disclosed herein is a system comprising at least one processor and instructions executable by the at least one processor to cause the at least one processor to perform operations comprising: (a) receiving a first dataset comprising one or more unknown objects and a second dataset comprising a set of reference objects, wherein the set of reference objects comprises a set of reference embeddings associated with instances of a class of at least one unknown object or the reference objects; (b) generating a set of input embeddings of the one or more unknown objects by applying an encoder to the first dataset; (c) generating a set of correlated embeddings of the one or more unknown objects by applying a convolutional neural network (CNN) model to the set of input embeddings and the set of reference embeddings, wherein the set of correlated embeddings is used to generate at least a detection overlay of the one or more unknown objects; (d) generating a set of referenced-attentioned embeddings of the one or more unknown objects by applying a referenced-attentioned model to the set of input embeddings and the set of reference embeddings, wherein the set of referenced-attentioned embeddings is used to generate at least a segmentation overlay of the one or more unknown objects; and (e) training a machine learning (ML) model using at least one of the detection overlay or the segmentation overlay, wherein the trained ML model is used to predict at least one of a set of detection characteristics or a set of segmentation characteristics with a confidence score.

In some cases, the system is provided to execute SiliconBASE: Multi-Task Baseline Model for Semiconductor Metrology and Inspection Applications.

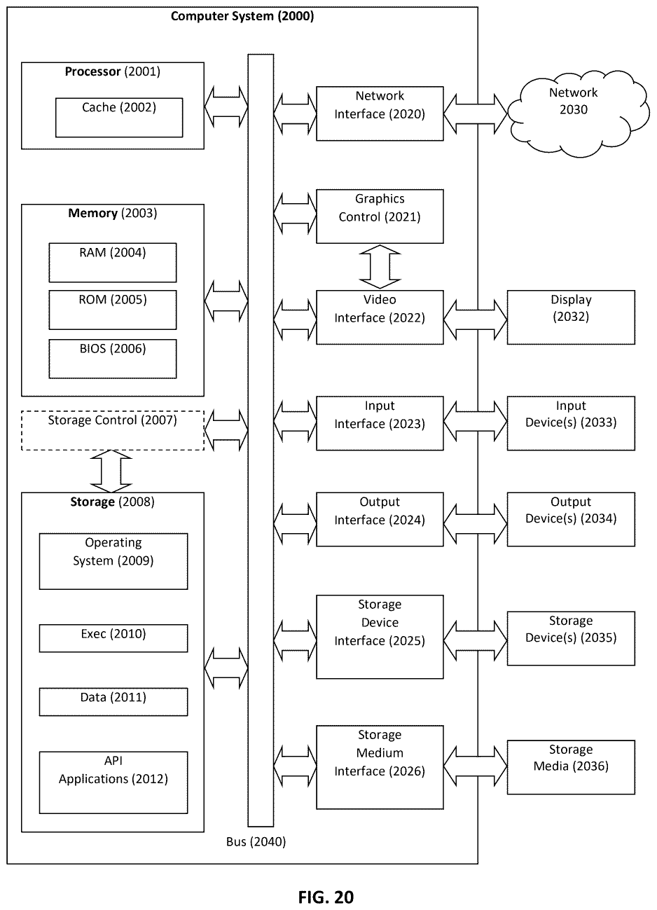

Referring to FIG. 20, a block diagram is shown depicting an exemplary machine that includes a computer system 2000 (e.g., a processing or computing system) within which a set of instructions can execute for causing a device to perform or execute any one or more of the aspects and/or methodologies for static code scheduling of the present disclosure. The components in FIG. 20 are examples only and do not limit the scope of use or functionality of any hardware, software, embedded logic component, or a combination of two or more such components implementing particular embodiments.

Computer system 2000 may include one or more processors 2001, a memory 2003, and a storage 2008 that communicate with each other, and with other components, via a bus 2040. The bus 2040 may also link a display 2032, one or more input devices 2033 (which may, for example, include a keypad, a keyboard, a mouse, a stylus, etc.), one or more output devices 2034, one or more storage devices 2035, and various tangible storage media 2036. All of these elements may interface directly or via one or more interfaces or adaptors to the bus 2040. For instance, the various tangible storage media 2036 can interface with the bus 2040 via storage medium interface 2026. Computer system 2000 may have any suitable physical form, including but not limited to one or more integrated circuits (ICs), printed circuit boards (PCBs), mobile handheld devices (such as mobile telephones or PDAs), laptop or notebook computers, distributed computer systems, computing grids, or servers.

Computer system 2000 includes one or more processor(s) 2001 (e.g., central processing units (CPUs) or general-purpose graphics processing units (GPGPUs)) that carry out functions. Processor(s) 701 optionally contains a cache memory unit 2002 for temporary local storage of instructions, data, or computer addresses. Processor(s) 2001 are configured to assist in execution of computer readable instructions. Computer system 2000 may provide functionality for the components depicted in FIG. 20 as a result of the processor(s) 2001 executing non-transitory, processor-executable instructions embodied in one or more tangible computer-readable storage media, such as memory 2003, storage 2008, storage devices 2035, and/or storage medium 2036. The computer-readable media may store software that implements particular embodiments, and processor(s) 2001 may execute the software. Memory 2003 may read the software from one or more other computer-readable media (such as mass storage device(s) 2035, 2036) or from one or more other sources through a suitable interface, such as network interface 2020. The software may cause processor(s) 2001 to carry out one or more processes or one or more steps of one or more processes described or illustrated herein. Carrying out such processes or steps may include defining data structures stored in memory 2003 and modifying the data structures as directed by the software.

The memory 2003 may include various components (e.g., machine readable media) including, but not limited to, a random access memory component (e.g., RAM 2004) (e.g., static RAM (SRAM), dynamic RAM (DRAM), ferroelectric random access memory (FRAM), phase-change random access memory (PRAM), etc.), a read-only memory component (e.g., ROM 2005), and any combinations thereof. ROM 2005 may act to communicate data and instructions unidirectionally to processor(s) 2001, and RAM 2004 may act to communicate data and instructions bidirectionally with processor(s) 2001. ROM 2005 and RAM 2004 may include any suitable tangible computer-readable media described below. In one example, a basic input/output system 2006 (BIOS), including basic routines that help to transfer information between elements within computer system 2000, such as during start-up, may be stored in the memory 2003.

Fixed storage 2008 is connected bidirectionally to processor(s) 2001, optionally through storage control unit 2007. Fixed storage 2008 provides additional data storage capacity and may also include any suitable tangible computer-readable media described herein. Storage 2008 may be used to store operating system 2009, executable(s) 2010, data 2011, applications 2012 (application programs), and the like. Storage 2008 can also include an optical disk drive, a solid-state memory device (e.g., flash-based systems), or a combination of any of the above. Information in storage 2008 may, in appropriate cases, be incorporated as virtual memory in memory 2003.

In one example, storage device(s) 2035 may be removably interfaced with computer system 2000 (e.g., via an external port connector (not shown)) via a storage device interface 2025. Particularly, storage device(s) 2035 and an associated machine-readable medium may provide non-volatile and/or volatile storage of machine-readable instructions, data structures, program modules, and/or other data for the computer system 2000. In one example, software may reside, completely or partially, within a machine-readable medium on storage device(s) 2035. In another example, software may reside, completely or partially, within processor(s) 2001.

Bus 2040 connects a wide variety of subsystems. Herein, reference to a bus may encompass one or more digital signal lines serving a common function, where appropriate. Bus 2040 may be any of several types of bus structures including, but not limited to, a memory bus, a memory controller, a peripheral bus, a local bus, and any combinations thereof, using any of a variety of bus architectures. As an example and not by way of limitation, such architectures include an Industry Standard Architecture (ISA) bus, an Enhanced ISA (EISA) bus, a Micro Channel Architecture (MCA) bus, a Video Electronics Standards Association local bus (VLB), a Peripheral Component Interconnect (PCI) bus, a PCI-Express (PCI-X) bus, an Accelerated Graphics Port (AGP) bus, HyperTransport (HTX) bus, serial advanced technology attachment (SATA) bus, and any combinations thereof.

Computer system 2000 may also include an input device 2033. In one example, a user of computer system 2000 may enter commands and/or other information into computer system 2000 via input device(s) 2033. Examples of an input device(s) 2033 include, but are not limited to, an alpha-numeric input device (e.g., a keyboard), a pointing device (e.g., a mouse or touchpad), a touchpad, a touch screen, a multi-touch screen, a joystick, a stylus, a gamepad, an audio input device (e.g., a microphone, a voice response system, etc.), an optical scanner, a video or still image capture device (e.g., a camera), and any combinations thereof. In some embodiments, the input device is a Kinect®, Leap Motion®, or the like. Input device(s) 2033 may be interfaced to bus 2040 via any of a variety of input interfaces 2023 (e.g., input interface 2023) including, but not limited to, serial, parallel, game port, USB, FIREWIRE, THUNDERBOLT, or any combination of the above.

In particular embodiments, when computer system 2000 is connected to network 2030, computer system 2000 may communicate with other devices, specifically mobile devices and enterprise systems, distributed computing systems, cloud storage systems, cloud computing systems, and the like, connected to network 2030. Communications to and from computer system 2000 may be sent through network interface 2020. For example, network interface 2020 may receive incoming communications (such as requests or responses from other devices) in the form of one or more packets (such as Internet Protocol (IP) packets) from network 2030, and computer system 2000 may store the incoming communications in memory 2003 for processing. Computer system 2000 may similarly store outgoing communications (such as requests or responses to other devices) in the form of one or more packets in memory 2003 and communicated to network 2030 from network interface 2020. Processor(s) 2001 may access these communication packets stored in memory 2003 for processing.

Examples of the network interface 2020 include, but are not limited to, a network interface card, a modem, and any combination thereof. Examples of a network 2030 or network segment 2030 include, but are not limited to, a distributed computing system, a cloud computing system, a wide area network (WAN) (e.g., the Internet, an enterprise network), a local area network (LAN) (e.g., a network associated with an office, a building, a campus or other relatively small geographic space), a telephone network, a direct connection between two computing devices, a peer-to-peer network, and any combinations thereof. A network, such as network 2030, may employ a wired and/or a wireless mode of communication. In general, any network topology may be used.

Information and data can be displayed through a display 2032. Examples of a display 2032 include, but are not limited to, a cathode ray tube (CRT), a liquid crystal display (LCD), a thin film transistor liquid crystal display (TFT-LCD), an organic liquid crystal display (OLED) such as a passive-matrix OLED (PMOLED) or active-matrix OLED (AMOLED) display, a plasma display, and any combinations thereof. The display 2032 can interface to the processor(s) 2001, memory 2003, and fixed storage 2008, as well as other devices, such as input device(s) 2033, via the bus 2040. The display 2032 is linked to the bus 2040 via a video interface 2022, and transport of data between the display 2032 and the bus 2040 can be controlled via the graphics control 2021. In some embodiments, the display is a video projector. In some embodiments, the display is a head-mounted display (HMD) such as a VR headset. In further embodiments, suitable VR headsets include, by way of non-limiting examples, HTC Vive®, Oculus Rift®, Samsung Gear VR®, Microsoft HoloLens®, Razer OSVR®, FOVE VR®, Zeiss VR One®, Avegant Glyph®, Freefly VR® headset, and the like. In still further embodiments, the display is a combination of devices such as those disclosed herein.

In addition to a display 2032, computer system 2000 may include one or more other peripheral output devices 2034 including, but not limited to, an audio speaker, a printer, a storage device, and any combinations thereof. Such peripheral output devices may be connected to the bus 2040 via an output interface 2024. Examples of an output interface 2024 include, but are not limited to, a serial port, a parallel connection, a USB port, a FIREWIRE port, a THUNDERBOLT port, and any combinations thereof.

In addition or as an alternative, computer system 2000 may provide functionality as a result of logic hardwired or otherwise embodied in a circuit, which may operate in place of or together with software to execute one or more processes or one or more steps of one or more processes described or illustrated herein. Reference to software in this present disclosure may encompass logic, and reference to logic may encompass software. Moreover, reference to a computer-readable medium may encompass a circuit (such as an IC) storing software for execution, a circuit embodying logic for execution, or both, where appropriate. The present disclosure encompasses any suitable combination of hardware, software, or both.

Various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by one or more processor(s), or in a combination of the two. A software module may reside in RAM memory, flash memory, ROM memory, EPROM memory, EEPROM memory, registers, hard disk, a removable disk, a CD-ROM, or any other form of storage medium. An exemplary storage medium is coupled to the processor such the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In accordance with the description herein, suitable computing devices include, by way of non-limiting examples, server computers, desktop computers, laptop computers, notebook computers, sub-notebook computers, netbook computers, netpad computers, set-top computers, media streaming devices, handheld computers, Internet appliances, mobile smartphones, tablet computers, personal digital assistants, video game consoles, and vehicles. Select televisions, video players, and digital music players with optional computer network connectivity are suitable for use in the system described herein. Suitable tablet computers, in various embodiments, include those with booklet, slate, and convertible configurations.

In some embodiments, the computing device includes an operating system configured to perform executable instructions. The operating system is, for example, software, including programs and data, which manages the device's hardware and provides services for execution of applications. Suitable server operating systems include, by way of non-limiting examples, FreeBSD®, OpenBSD®, NetBSD®, Linux®, Apple® Mac OS X Server®, Oracle Solaris®, Windows Server®, and Novell NetWare®. Suitable personal computer operating systems include, by way of non-limiting examples, Microsoft Windows®, Apple Mac® OS X, UNIX®, and UNIX-like operating systems such as GNU/Linux®. In some embodiments, the operating system is provided by cloud computing. Suitable mobile smartphone operating systems include, by way of non-limiting examples, Nokia Symbian® OS, Apple® iOS, Research In Motion BlackBerry® OS, Google® Android®, Microsoft® Windows Phone® OS, Microsoft® Windows Mobile OS, Linux®, and Palm® WebOS. Suitable media streaming device operating systems include, by way of non-limiting examples, Apple TV®, Roku®, Boxee®, Google TV®, Google Chromecast®, Amazon Fire®, and Samsung® HomeSync®. Suitable video game console operating systems include, by way of non-limiting examples, Sony® PS3®, Sony® PS4®, Microsoft® Xbox 360®, Microsoft Xbox One®, Nintendo Wii®, Nintendo Wii U®, and Ouya®. Suitable virtual reality headset systems include, by way of non-limiting example, Meta Oculus®.

### Non-Transitory Computer Readable Storage Mediums

In some embodiments, the platforms, systems, media, and methods disclosed herein include one or more non-transitory computer readable storage media encoded with a program including instructions executable by the operating system of an optionally networked computing device. In further embodiments, a computer readable storage medium is a tangible component of a computing device. In still further embodiments, a computer readable storage medium is optionally removable from a computing device. In some embodiments, a computer readable storage medium includes, by way of non-limiting examples, CD-ROMs, DVDs, flash memory devices, solid state memory, magnetic disk drives, magnetic tape drives, optical disk drives, distributed computing systems including cloud computing systems and services, and the like. In some cases, the program and instructions are permanently, substantially permanently, semi-permanently, or non-transitorily encoded on the media.

### Computer Programs

In another aspect, disclosed herein is a computer program product for unsupervised detection and segmentation of unknown objects, the computer program product comprising at least one non-transitory computer-readable medium having computer-readable program code portions embodied therein, the computer-readable program code portions comprising: an executable portion configured receive a first dataset comprising one or more unknown objects and a second dataset comprising a set of reference objects, wherein the set of reference objects comprises a set of reference embeddings associated with instances of a class of at least one unknown object or the reference objects; an executable portion configured to generate a set of input embeddings of the one or more unknown objects by applying an encoder to the first dataset; an executable portion configured to generate a set of correlated embeddings of the one or more unknown objects by applying a convolutional neural network (CNN) model to the set of input embeddings and the set of reference embeddings, wherein the set of correlated embeddings is used to generate at least a detection overlay of the one or more unknown objects; an executable portion configured to generate a set of referenced-attentioned embeddings of the one or more unknown objects by applying a referenced-attentioned model to the set of input embeddings and the set of reference embeddings, wherein the set of referenced-attentioned embeddings is used to generate at least a segmentation overlay of the one or more unknown objects; and an executable portion configured to train a machine learning (ML) model using at least one of the detection overlay or the segmentation overlay, wherein the trained ML model is used to predict at least one of a set of detection characteristics or a set of segmentation characteristics with a confidence score.

In some cases, the computer program product is provided to execute SiliconBASE: Multi-Task Baseline Model for Semiconductor Metrology and Inspection Applications.

In some embodiments, the platforms, systems, media, and methods disclosed herein include at least one computer program, or use of the same. A computer program includes a sequence of instructions, executable by one or more processor(s) of the computing device's CPU, written to perform a specified task. Computer readable instructions may be implemented as program modules, such as functions, objects, Application Programming Interfaces (APIs), computing data structures, and the like, that perform particular tasks or implement particular abstract data types. In light of the present disclosure provided herein, a computer program may be written in various versions of various languages.

The functionality of the computer readable instructions may be combined or distributed as desired in various environments. In some embodiments, a computer program comprises one sequence of instructions. In some embodiments, a computer program comprises a plurality of sequences of instructions. In some embodiments, a computer program is provided from one location. In other embodiments, a computer program is provided from a plurality of locations. In various embodiments, a computer program includes one or more software modules. In various embodiments, a computer program includes, in part or in whole, one or more web applications, one or more mobile applications, one or more standalone applications, one or more web browser plug-ins, extensions, add-ins, or add-ons, or combinations thereof.

### Web Applications

In some embodiments, a computer program includes a web application. In light of the present disclosure provided herein, a web application, in various embodiments, utilizes one or more software frameworks and one or more database systems. In some embodiments, a web application is created upon a software framework such as Microsoft® NET or Ruby on Rails® (RoR). In some embodiments, a web application utilizes one or more database systems including, by way of non-limiting examples, relational, non-relational, object oriented, associative, and XML database systems. In further embodiments, suitable relational database systems include, by way of non-limiting examples, Microsoft® structured query language (SQL) Server, mySQL™, and Oracle®. A web application, in various embodiments, is written in one or more versions of one or more languages. A web application may be written in one or more markup languages, presentation definition languages, client-side scripting languages, server-side coding languages, database query languages, or combinations thereof. In some embodiments, a web application is written to some extent in a markup language such as Hypertext Markup Language (HTML), Extensible Hypertext Markup Language (XHTML), or extensible Markup Language (XML). In some embodiments, a web application is written to some extent in a presentation definition language such as Cascading Style Sheets (CSS). In some embodiments, a web application is written to some extent in a client-side scripting language such as Asynchronous Javascript and XML® (AJAX), Flash Actionscript, Javascript®, or Silverlight®. In some embodiments, a web application is written to some extent in a server-side coding language such as Active Server Pages® (ASP), ColdFusion®, Perl®, Java®, JavaServer Pages® (JSP), Hypertext Preprocessor® (PHP), Python®, Ruby®, Tcl®, Smalltalk®, WebDNA®, or Groovy®. In some embodiments, a web application is written to some extent in a database query language such as Structured Query Language (SQL). In some embodiments, a web application integrates enterprise server products such as IBM Lotus Domino®. In some embodiments, a web application includes a media player element. In various further embodiments, a media player element utilizes one or more of many suitable multimedia technologies including, by way of non-limiting examples, Adobe® Flash®, HTML 5, Apple® QuickTime®, Microsoft Silverlight®, Java®, and Unity®.

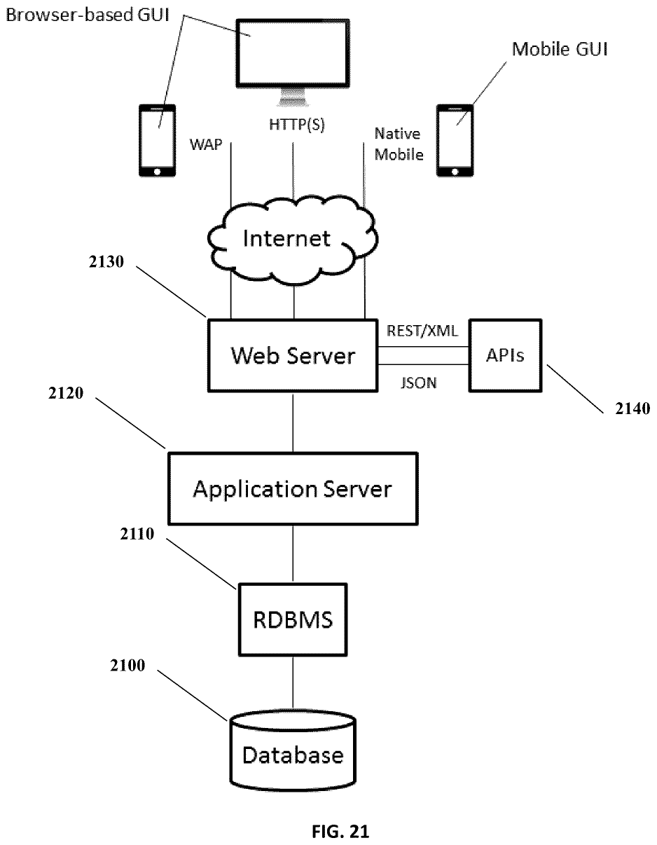

Referring to FIG. 21, in a particular embodiment, an application provision system comprises one or more databases 2100 accessed by a database management system (DBMS) 2110. Suitable DBMSs include Firebird®, MySQL®, NOSQL®, PostgreSQL®, SQLite®, Oracle Database®, Microsoft SQL Server®, IBM DB2®, IBM Informix®, SAP Sybase®, SAP Sybase®, Teradata®, PostGIS®, Apache® Hive, Apache® Impala, time-series databases, graph databases, key-value storage, and the like. In this embodiment, the application provision system further comprises one or more application severs 2120 (such as Java® servers, .NET® servers, PHP® servers, and the like) and one or more web servers 2130 (such as Apache®, IIS®, GWS® and the like). The web server(s) optionally expose one or more web services via app application programming interfaces (APIs) 2140. Via a network, such as the Internet, the system provides browser-based and/or mobile native user interfaces. In some cases, a DBMS may be a relational DBMS.

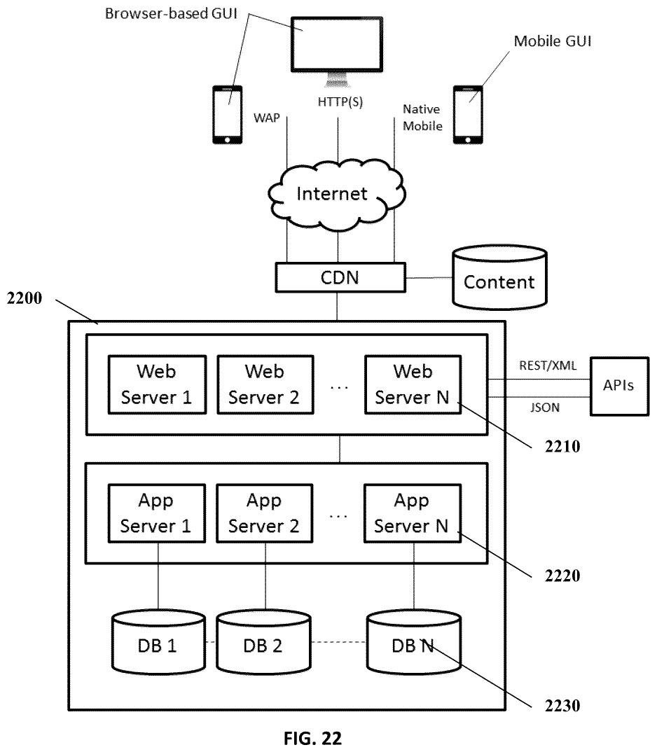

Referring to FIG. 22, in a particular embodiment, an application provision system alternatively has a distributed, cloud-based architecture 2200 and comprises elastically load balanced, auto-scaling web server resources 2210 and application server resources 2220 as well synchronously replicated databases 2230.

### Mobile Applications

In some embodiments, a computer program includes a mobile application provided to a mobile computing device. In some embodiments, the mobile application is provided to a mobile computing device at the time it is manufactured. In other embodiments, the mobile application is provided to a mobile computing device via the computer network described herein.

In view of the present disclosure provided herein, a mobile application is created by techniques using hardware, languages, and development environments. Mobile applications are written in several languages. Suitable programming languages include, by way of non-limiting examples, C, C++, C#, Objective-C, Java®, Javascript®, Pascal®, Object Pascal®, Python™, Ruby®, VB.NET®, WML®, and XHTML/HTML with or without CSS, or combinations thereof.

Suitable mobile application development environments are available from several sources. Commercially available development environments include, by way of non-limiting examples, AirplaySDK®, alcheMo®, Appcelerator®, Celsius®, Bedrock®, Flash Lite®, .NET Compact Framework®, Rhomobile®, and WorkLight Mobile Platform®. Other development environments are available without cost including, by way of non-limiting examples, Lazarus® MobiFlex®, MoSync®, and Phonegap®. Also, mobile device manufacturers distribute software developer kits including, by way of non-limiting examples, iPhone® and iPad® (iOS) SDK, Android® SDK, BlackBerry® SDK, BREW SDK, Palm® OS SDK, Symbian® SDK, webOS® SDK, and Windows® Mobile SDK.

Several commercial sources are available for distribution of mobile applications including, by way of non-limiting examples, Apple® App Store, Google® Play, Chrome® WebStore, BlackBerry® App World, App Store® for Palm devices, App Catalog® for webOS, Windows® Marketplace for Mobile, Ovi Store for Nokia® devices, Samsung® Apps, and Nintendo® DSi Shop.

### Standalone Applications

In some embodiments, a computer program includes a standalone application, which is a program that is run as an independent computer process, not an add-on to an existing process, e.g., not a plug-in. Standalone applications are often compiled. A compiler is a computer program(s) that transforms source code written in a programming language into binary object code such as assembly language or machine code. Suitable compiled programming languages include, by way of non-limiting examples, C, C++, Objective-C®, COBOL®, Delphi®, Eiffel®, Java®, Lisp®, Python®, Visual Basic®, and VB.NET®, or combinations thereof. Compilation is often performed, at least in part, to create an executable program. In some embodiments, a computer program includes one or more executable compiled applications. Additionally, microservices related to Python® and JavaScript® may be used.

### Web Browser Plug-Ins

In some embodiments, the computer program includes a web browser plug-in (e.g., web extension, etc.). In computing, a plug-in is one or more software components that add specific functionality to a larger software application. Makers of software applications support plug-ins to enable third-party developers to create abilities which extend an application, to support easily adding new features, and to reduce the size of an application. When supported, plug-ins enable customizing the functionality of a software application. For example, plug-ins are commonly used in web browsers to play video, generate interactivity, scan for viruses, and display particular file types. Several web browser plug-ins may include Adobe Flash Player®, Microsoft Silverlight®, and Apple QuickTime®. In some embodiments, the toolbar comprises one or more web browser extensions, add-ins, or add-ons. In some embodiments, the toolbar comprises one or more explorer bars, tool bands, or desk bands.

In view of the present disclosure provided herein, several plug-in frameworks are available that enable development of plug-ins in various programming languages, including, by way of non-limiting examples, C++, Delphi®, Java®, PHP®, Python®, and VB.NET®, or combinations thereof.

Web browsers (also called Internet browsers) are software applications, designed for use with network-connected computing devices, for retrieving, presenting, and traversing information resources on the World Wide Web. Suitable web browsers include, by way of non-limiting examples, Microsoft Internet Explorer®, Mozilla Firefox®, Google Chrome®, Apple Safari®, Opera Software Opera®, and KDE Konqueror®. In some embodiments, the web browser is a mobile web browser. Mobile web browsers (also called microbrowsers, mini-browsers, and wireless browsers) are designed for use on mobile computing devices including, by way of non-limiting examples, handheld computers, tablet computers, netbook computers, subnotebook computers, smartphones, music players, personal digital assistants (PDAs), and handheld video game systems. Suitable mobile web browsers include, by way of non-limiting examples, Google Android® browser, RIM Blackberry® Browser, Apple Safari®, Palm Blazer®, Palm WebOS® Browser, Mozilla Firefox® for mobile, Microsoft Internet Explorer Mobile®, Amazon Kindle Basic Web®, Nokia Browser®, Opera Software Opera Mobile®, and Sony PSP® browser.

### Software Modules

In some embodiments, the platforms, systems, media, and methods disclosed herein include software, server, and/or database modules, or use of the same. In view of the present disclosure provided herein, software modules are created by techniques using machines, software, and languages. The software modules disclosed herein are implemented in a multitude of ways. In various embodiments, a software module comprises a file, a section of code, a programming object, a programming structure, or combinations thereof. In further various embodiments, a software module comprises a plurality of files, a plurality of sections of code, a plurality of programming objects, a plurality of programming structures, or combinations thereof. In various embodiments, the one or more software modules comprise, by way of non-limiting examples, a web application, a mobile application, and a standalone application. In some embodiments, software modules are in one computer program or application. In other embodiments, software modules are in more than one computer program or application. In some embodiments, software modules are hosted on one machine. In other embodiments, software modules are hosted on more than one machine. In further embodiments, software modules are hosted on a distributed computing platform such as a cloud computing platform. In some embodiments, software modules are hosted on one or more machines in one location. In other embodiments, software modules are hosted on one or more machines in more than one location.

### Databases

In some embodiments, the platforms, systems, media, and methods disclosed herein include one or more databases (DB), or use of the same. In view of the present disclosure provided herein, many databases are suitable for storage and retrieval data. In various embodiments, suitable databases include, by way of non-limiting examples, relational databases, non-relational databases, object oriented databases, object databases, entity-relationship model databases, associative databases, XML databases, time-series databases, graph databases, and the like. Further non-limiting examples include SQL, PostgreSQL®, MySQL®, Oracle®, DB2®, and Sybase. In some embodiments, a database is internet-based. In further embodiments, a database is web-based. In still further embodiments, a database is cloud computing-based. In a particular embodiment, a database is a distributed database. In other embodiments, a database is based on one or more local computer storage devices.

### Terms and Definitions

Unless otherwise defined, all technical terms used herein have the same meaning as commonly understood by one of ordinary skill in the art to which this present disclosure belongs.

As used herein, the singular forms “a,” “an,” and “the” include plural references unless the context clearly dictates otherwise. Any reference to “or” herein is intended to encompass “and/or” unless otherwise stated.

As used herein, the term “about” in some cases refers to an amount that is approximately the stated amount.

As used herein, the term “about” refers to an amount that is near the stated amount by 10%, 5%, or 1%, including increments therein.

As used herein, the term “about” in reference to a percentage refers to an amount that is greater or less the stated percentage by 10%, 5%, or 1%, including increments therein.

As used herein, the phrases “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

While preferred embodiments of the present disclosure have been shown and described herein, such embodiments are provided by way of example only. It is not intended that the present disclosure be limited by the specific examples provided within the specification. While the present disclosure has been described with reference to the aforementioned specification, the descriptions and illustrations of the embodiments herein are not meant to be construed in a limiting sense. Numerous variations, changes, and substitutions may occur without departing from the present disclosure. Furthermore, it shall be understood that all aspects of the present disclosure are not limited to the specific depictions, configurations, or relative proportions set forth herein which depend upon a variety of conditions and variables. It should be understood that various alternatives to the embodiments of the present disclosure described herein may be employed in practicing the present disclosure. It is therefore contemplated that the present disclosure shall also cover any such alternatives, modifications, variations, or equivalents. It is intended that the following claims define the scope of the present disclosure and that systems, methods and structures within the scope of these claims and their equivalents be covered thereby.

1. A method for unsupervised detection and segmentation of unknown objects, the method comprising:
(a) receiving a first dataset comprising one or more unknown objects and a second dataset comprising a set of reference objects, wherein the set of reference objects comprises a set of reference embeddings associated with instances of a class of at least one unknown object or the reference objects;
(b) generating a set of input embeddings of the one or more unknown objects by applying an encoder to the first dataset;
(c) generating a set of correlated embeddings of the one or more unknown objects by applying a convolutional neural network (CNN) model to the set of input embeddings and the set of reference embeddings, wherein the set of correlated embeddings is used to generate at least a detection overlay of the one or more unknown objects;
(d) generating a set of referenced-attentioned embeddings of the one or more unknown objects by applying a referenced-attentioned model to the set of input embeddings and the set of reference embeddings, wherein the set of referenced-attentioned embeddings is used to generate at least a segmentation overlay of the one or more unknown objects; and
(e) training a machine learning (ML) model using at least one of the detection overlay or the segmentation overlay, wherein the trained ML model is used to predict at least one of a set of detection characteristics or a set of segmentation characteristics with a confidence score.

2. The method of claim 1, further comprising predicting, by the trained ML model, at least one of (i) a set of detection characteristics of the one or more unknown objects or (ii) a set of detection characteristics of other objects of the same class.

3. The method of claim 2, wherein each set of detection characteristics comprises at least a location of the one or more unknown objects or locations of the other objects patterned on a wafer using a semiconductor process.

4. The method of claim 1, further comprising predicting, by the trained ML model, at least one of (i) a set of segmentation characteristics of the one or more unknown objects or (ii) a set of segmentation characteristics of other objects of the same class.

5. The method of claim 4, wherein each set of segmentation characteristics comprises at least metrology measurements of the one or more unknown objects or metrology measurements of the other objects, patterned on a wafer using a semiconductor process.

6. The method of claim 1, wherein the first dataset comprises at least an image of the one or more unknown objects patterned on a wafer using a semiconductor process.

7. The method of claim 1, wherein the first dataset comprises at least an image of the one or more unknown objects obtained using scanning electron microscopy (SEM) or transmission electron microscopy (TEM).

8. The method of claim 1, wherein the second dataset comprises at least images of the set of reference objects patterned on a wafer using a semiconductor process.

9. The method of claim 1, wherein the second dataset comprises at least images of the set of reference objects obtained using scanning electron microscopy (SEM) or transmission electron microscopy (TEM).

10. The method of claim 1, further comprising generating the set of input embeddings by using a vision encoder to determine a dimension of the first dataset comprising a number of channels and a size.

11. The method of claim 1, further comprising generating the set of correlated embeddings by using a mask region-based CNN (mask-RCNN) model comprising a dynamic anchor model to determine a grid of base anchors of the first dataset or the set of reference objects.

12. The method of claim 1, further comprising generating the set of referenced-attentioned embeddings by using a multi-head attention model to obtain a low-resolution reference-attentioned mask and a high-resolution reference-attentioned mask.

13. The method of claim 1, further comprising generating the instances of the class of the at least one unknown object by applying a set of operations to the first dataset thereby obtaining the second dataset.

14. The method of claim 1, further comprising using an output of the trained ML model in reference object detection (ROD) in a semiconductor process for determining a set of detection characteristics of the one or more unknown objects or a plurality of other objects patterned by a semiconductor process.

15. The method of claim 14, wherein each set of detection characteristics comprises at least one of (i) a set of positioning measurement locations of the one or more unknown objects or the plurality of other objects or (ii) an issue in a hierarchical structure comprising the one or more unknown objects or the plurality of other objects, patterned by the semiconductor process.

16. The method of claim 1, further comprising using an output of the trained ML model in reference object segmentation (ROS) in a semiconductor process for determining a set of segmentation characteristics of the one or more unknown objects or a plurality of other objects patterned by a semiconductor process.

17. The method of claim 16, wherein each set of segmentation characteristics comprises at least a metrology of the one or more unknown objects or the plurality of other objects, patterned by the semiconductor process.

18. The method of claim 1, further comprising using an output of the trained ML model in metrology and inspection (MI) in a semiconductor process for characterizing at least a metrology of the one or more unknown objects or a plurality of other objects, patterned by a semiconductor process.

19. The method of claim 1, further comprising removing artifacts from the first dataset or the second dataset prior to determining the set of correlated embeddings.

20. The method of claim 1, wherein the detection overlay or the segmentation overlay is embedded with data associated with a class of the at least one unknown object, a confidence score of the class, a label of the at least one unknown object, a confidence score of the label, an identification of the at least one unknown object, or a confidence score of the identification.

21. The method of claim 1, wherein the trained ML model is trained by using reference-based training on the first dataset or the second dataset.

22. The method of claim 1, wherein the trained ML model is validated by determining (i) a difference between the detection overlay and a detection overlay determined by domain expertise or (ii) a difference between the segmentation overlay and a segmentation overlay determined by domain expertise.

23. The method of claim 1, further comprising repeating the method until determining the detection overlay or the segmentation overlay for all unknown objects or substantially all unknown objects of the first dataset.

24. The method of claim 1, wherein an accuracy of the trained ML model is determined using average precision (AP), average recall, or mean intersection over the union (IOU).

25. The method of claim 24, wherein the accuracy is at least 90%.

26. The method of claim 1, further comprising using an output of the trained ML model to determine or predict an anomaly in an unknown object patterned on a wafer using a semiconductor process.

27. The method of claim 1, further comprising using an output of the trained ML model to search for an unknown object patterned on a wafer using a semiconductor process.

28. (canceled)

29. A system comprising at least one processor and instructions executable by the at least one processor to cause the at least one processor to perform operations comprising:
(a) receiving a first dataset comprising one or more unknown objects and a second dataset comprising a set of reference objects, wherein the set of reference objects comprises a set of reference embeddings associated with instances of a class of at least one unknown object or the reference objects;
(b) generating a set of input embeddings of the one or more unknown objects by applying an encoder to the first dataset;
(c) generating a set of correlated embeddings of the one or more unknown objects by applying a convolutional neural network (CNN) model to the set of input embeddings and the set of reference embeddings, wherein the set of correlated embeddings is used to generate at least a detection overlay of the one or more unknown objects;
(d) generating a set of referenced-attentioned embeddings of the one or more unknown objects by applying a referenced-attentioned model to the set of input embeddings and the set of reference embeddings, wherein the set of referenced-attentioned embeddings is used to generate at least a segmentation overlay of the one or more unknown objects; and
(e) training a machine learning (ML) model using at least one of the detection overlay or the segmentation overlay, wherein the trained ML model is used to predict at least one of a set of detection characteristics or a set of segmentation characteristics with a confidence score.
